(19) United States
(12) Patent Application Publication
(10) Pub. No.: US 2026/0188239 A1
(43) Pub. Date: Jul. 2, 2026

(54) Shift Register and Driving Method Thereof, Gate Driving Circuit and Display Device

(71) Applicants: Hefei BOE Joint Technology Co., Ltd., Hefei, Anhui (CN); BOE TECHNOLOGY GROUP CO., LTD., Chaoyang District, Beijing (CN)

(72) Inventors: Xuehuan Feng, Beijing (CN); Yongqian Li, Beijing (CN)

(21) Appl. No.: 18/857,366

(22) PCT Filed: Sep. 20, 2023
(86) PCT No.: PCT/CN2023/120022

§ 371 Date: Oct. 16, 2024

(51) Int. Cl. G09G 3/3266; G09G 3/20; G09G 3/3258; G11C 19/28

(52) U.S. Cl. CPC G09G 3/3266; G09G 3/3258; G11C 19/28; G09G 3/2074; G09G 2300/0842; G09G 2310/0286; G09G 2310/08; G09G 2320/0257; G09G 2330/023

(57) ABSTRACT

A shift register includes a first decode sub-circuit and a third control sub-circuit. The first decode sub-circuit is configured to select the shift register to output no scanning signal under control of an operating voltage from at least one selection control signal terminal and a second clock signal, or select the shift register to output a scanning signal under control of a non-operating voltage of each selection control signal terminal of a plurality of selection control signal terminals and the second clock signal. The third control sub-circuit is configured to transmit a first voltage signal to a second node and the a signal output terminal in a case where the shift register is selected to output no scanning signal, and transmit the first voltage signal to a third node in a case where the shift register is selected to output a scanning signal.

### CROSS-REFERENCE TO RELATED APPLICATION

This application is the United States national phase of International Patent Application No. PCT/CN2023/120022, filed Sep. 20, 2023, the disclosure of which is hereby incorporated by reference in its entirety.

### BACKGROUND OF THE INVENTION

### Field of the Invention

The present disclosure relates to the field of display technologies, and in particular, to a shift register and a driving method thereof, a gate driving circuit, and a display device.

### Description of Related Art

With the continuous development of display technologies, narrow bezel and high refresh rate display devices have become one of the mainstream development trends in the display field. The organic light-emitting diode (OLED) display device is becoming one of the mainstream products in the display field due to its excellent performance such as self-luminous, no need for a backlight source, high contrast, small thickness, wide viewing angle, fast response speed, applicability to a flexible panel, wide temperature range for using, and relatively simple structure and process. A gate on array (GOA) technology is generally adopted in a display device to achieve narrow bezel or zero bezel of the display device.

### SUMMARY OF THE INVENTION

In an aspect, a shift register is provided. The shift register includes a first control sub-circuit, a first output sub-circuit, a second control sub-circuit, a second output sub-circuit, a first decode sub-circuit and a third control sub-circuit. The first control sub-circuit is electrically connected to a first clock signal terminal and a first node, and configured to transmit the first clock signal to the first node under control of a first clock signal from the first clock signal terminal. The first output sub-circuit is electrically connected to the first node, a first voltage signal terminal and a signal output terminal, and configured to transmit a first voltage signal from the first voltage signal terminal to the signal output terminal under control of a voltage of the first node. The second control sub-circuit is electrically connected to the first node, a second clock signal terminal and a second node, and configured to transmit the second clock signal to the second node under control of a second clock signal from the second clock signal terminal and the voltage of the first node. The second output sub-circuit is electrically connected to the second node, a third clock signal terminal and the signal output terminal, and configured to transmit a third clock signal from the third clock signal terminal to the signal output terminal under control of a voltage of the second node. The first decode sub-circuit is electrically connected to a plurality of selection control signal terminals, the second clock signal terminal and a third node, and configured to: select the shift register not to output a scanning signal under control of an operating voltage from at least one selection control signal terminal and the second clock signal, or select the shift register to output a scanning signal under control of a non-operating voltage of each selection control signal terminal of the plurality of selection control signal terminals and the second clock signal. The third control sub-circuit is electrically connected to the first voltage signal terminal, the second node, the third node and the signal output terminal, and configured to transmit the first voltage signal to the second node and the signal output terminal in a case where the shift register is selected to output no scanning signal, and transmit the first voltage signal to the third node in a case where the shift register is selected to output a scanning signal.

In some embodiments, the first decode sub-circuit includes a first transistor and a plurality of second transistors. A control electrode and a first electrode of the first transistor are both electrically connected to the second clock signal terminal, and a second electrode of the first transistor is electrically connected to a fourth node. A control electrode of each second transistor of the plurality of second transistors is electrically connected to a selection control signal terminal of the plurality of selection control signal terminals, first electrodes of the plurality of second transistors are all electrically connected to the fourth node, and second electrodes of the plurality of second transistors are all electrically connected to the third node.

In some embodiments, the first decode sub-circuit is further electrically connected to a second voltage signal terminal. The first decode sub-circuit includes a first transistor and a plurality of second transistors. A control electrode of the first transistor is electrically connected to the second clock signal terminal, a first electrode of the first transistor is electrically connected to a fifth node, and a second electrode of the first transistor is electrically connected to the third node. A control electrode of each second transistor of the plurality of second transistors is electrically connected to a selection control signal terminal of the plurality of selection control signal terminals, first electrodes of the plurality of second transistors are all electrically connected to the second voltage signal terminal, and second electrodes of the plurality of second transistors are all electrically connected to the fifth node.

In some embodiments, the shift transistor further includes a black frame insertion control sub-circuit. The black frame insertion control sub-circuit is electrically connected to a first control signal terminal, the fifth node and the signal output terminal, and configured to transmit a voltage of the fifth node to the signal output terminal under control of a first control signal from the first control signal terminal.

In some embodiments, the black frame insertion control sub-circuit includes a third transistor. A control electrode of the third transistor is electrically connected to the first control signal terminal, a first electrode of the third transistor is electrically connected to the fifth node, and a second electrode of the third transistor is electrically connected to the signal output terminal.

In some embodiments, the shift register further includes a second decode sub-circuit. The second decode sub-circuit is electrically connected to a plurality of black frame insertion control signal terminals, a first control signal terminal, the second voltage signal terminal and the signal output terminal, and configured to transmit a second voltage signal from the second voltage signal terminal to the signal output terminal under control of a black frame insertion control signal from at least one black frame insertion control signal terminal of the plurality of black frame insertion control signal terminals and a first control signal from the first control signal terminal.

In some embodiments, the second decode sub-circuit includes a fifth transistor and a plurality of fourth transistors. A control electrode of each fourth transistor of the plurality of fourth transistors is electrically connected to a black frame insertion control signal terminal of the plurality of black frame insertion control signal terminals, first electrodes of the plurality of fourth transistors are all electrically connected to the second voltage signal terminal, and second electrode of the plurality of fourth transistors are all electrically connected to a sixth node. A control electrode of the fifth transistor is electrically connected to the first control signal terminal, a first electrode of the fifth transistor is electrically connected to the sixth node, and a second electrode of the fifth transistor is electrically connected to the signal output terminal.

In some embodiments, a number of the plurality of black frame insertion control signal terminals is the same as a number of the plurality of selection control signal terminals, and the plurality of black frame insertion control signal terminals are in one-to-one correspondence with the plurality of selection control signal terminals. A black frame insertion control signal terminal of the plurality of black frame insertion control signal terminals and a selection control signal terminal corresponding to the black frame insertion control signal terminal are a same signal terminal or different signal terminals.

In some embodiments, the third control sub-circuit includes a sixth transistor, a seventh transistor and an eighth transistor. A control electrode of the sixth transistor is electrically connected to the third node, a first electrode of the sixth transistor is electrically connected to the first voltage signal terminal, and a second electrode of the sixth transistor is electrically connected to the second node. A control electrode of the seventh transistor is electrically connected to the third node, a first electrode of the seventh transistor is electrically connected to the first voltage signal terminal, and a second electrode of the seventh transistor is electrically connected to the signal output terminal. A control electrode of the eighth transistor is electrically connected to the second node, a first electrode of the eighth transistor is electrically connected to the first voltage signal terminal, and a second electrode of the eighth transistor is electrically connected to the third node.

In some embodiments, the sixth transistor is a dual-gate transistor, the sixth transistor includes two sub-transistors connected in series, and the two sub-transistors are connected through a seventh node. The shift register further includes an anti-leakage sub-circuit. The anti-electricity leakage sub-circuit is electrically connected to the second node, the second voltage signal terminal and the seventh node, and configured to transmit a second voltage signal to the seventh node under control of the voltage of the second node.

In some embodiments, the anti-leakage sub-circuit includes a ninth transistor. A control electrode of the ninth transistor is electrically connected to the second node, a first electrode of the ninth transistor is electrically connected to the second voltage signal terminal, and a second electrode of the ninth transistor is electrically connected to the seventh node.

In some embodiments, the third control sub-circuit is further electrically connected to the first node, and the third control sub-circuit is further configured to, in a case where the shift register is selected to output no scanning signal, transmit the first voltage signal to the first node.

In some embodiments, the third control sub-circuit further includes a tenth transistor. A control electrode of the tenth transistor is electrically connected to the third node, a first electrode of the tenth transistor is electrically connected to the first voltage signal terminal, and a second electrode of the tenth transistor is electrically connected to the first node.

In some embodiments, the shift register further includes a time-division selection sub-circuit and a fourth control sub-circuit. The time-sharing selection sub-circuit is electrically connected to a second control signal terminal, a third control signal terminal, the first decode sub-circuit, the third node and an eighth node. The time-division selection sub-circuit is configured to electrically connect the first decode sub-circuit to the third node under control of a second control signal from the second control signal terminal, and electrically connect the first decode sub-circuit to the eighth node under control of a third control signal from the third control signal terminal; the first decode sub-circuit is electrically connected to the third node through the time-division selection sub-circuit. The fourth control sub-circuit is electrically connected to the first voltage signal terminal, the second node, the eighth node and the signal output terminal. The fourth control sub-circuit is configured to transmit the first voltage signal to the second node and the signal output terminal in a case where the shift register is selected to output no scanning signal, and transmit the first voltage signal to the eighth node in a case where the shift register is selected to output a scanning signal. The first decode sub-circuit is electrically connected to the third node through the time-sharing selection sub-circuit.

In some embodiments, the time-sharing selection sub-circuit includes an eleventh transistor and a twelfth transistor. A control electrode of the eleventh transistor is electrically connected to the second control signal terminal, a first electrode of the eleventh transistor is electrically connected to the first decode sub-circuit, and a second electrode of the eleventh transistor is electrically connected to the third node. A control electrode of the twelfth transistor is electrically connected to the third control signal terminal, a first electrode of the twelfth transistor is electrically connected to the first decode sub-circuit, and a second electrode of the twelfth transistor is electrically connected to the eighth node. In a display period, one of the second control signal terminal and the third control signal terminal transmits a corresponding control signal, and the second control signal terminal and the third control signal terminal alternately transmit a corresponding control signal.

In some embodiments, the fourth control sub-circuit includes a thirteenth transistor, a fourteenth transistor, a fifteenth transistor and a sixteenth transistor. A control electrode of the thirteenth transistor is electrically connected to the eighth node, a first electrode of the thirteenth transistor is electrically connected to the first voltage signal terminal, and a second electrode of the thirteenth transistor is electrically connected to the second node. A control electrode of the fourteenth transistor is electrically connected to the eighth node, a first electrode of the fourteenth transistor is electrically connected to the first voltage signal terminal, and a second electrode of the fourteenth transistor is electrically connected to the signal output terminal. A control electrode of the fifteenth transistor is electrically connected to the second node, a first electrode of the fifteenth transistor is electrically connected to the first voltage signal terminal, and a second electrode of the fifteenth transistor is electrically connected to the eighth node. A control electrode of the sixteenth transistor is electrically connected to the eighth node, a first electrode of the sixteenth transistor is electrically connected to the first voltage signal terminal, and a second electrode of the sixteenth transistor is electrically connected to the first node.

In some embodiments, the first control sub-circuit includes a seventeenth transistor, a control electrode and a first electrode of the seventeenth transistor are both electrically connected to the first clock signal terminal, and a second electrode of the seventeenth transistor is electrically connected to the first node. The first output sub-circuit includes an eighteenth transistor, a control electrode of the eighteenth transistor is electrically connected to the first node, a first electrode of the eighteenth transistor is electrically connected to the first voltage signal terminal, and a second electrode of the eighteenth transistor is electrically connected to the signal output terminal. The second control sub-circuit includes a nineteenth transistor and a twentieth transistor, a control electrode and a first electrode of the nineteenth transistor are both electrically connected to the second clock signal terminal, and a second electrode of the nineteenth transistor is electrically connected to a first electrode of the twentieth transistor. A control electrode of the twentieth transistor is electrically connected to the first node, and a second electrode of the twentieth transistor is electrically connected to the second node. The second output sub-circuit includes a twenty-first transistor, a control electrode of the twenty-first transistor is electrically connected to the second node, a first electrode of the twenty-first transistor is electrically connected to the third clock signal terminal, and a second electrode of the twenty-first transistor is electrically connected to the signal output terminal.

In some embodiments, the shift register further includes a reset sub-circuit, an initialization sub-circuit, a first energy-storing sub-circuit, a second energy-storing sub-circuit and a third energy-storing sub-circuit. The reset sub-circuit is electrically connected to the third clock signal terminal, the first voltage signal terminal and the first node, and configured to transmit the first voltage signal to the first node under control of the third clock signal. The initialization sub-circuit is electrically connected to the first clock signal terminal, the first voltage signal terminal and the third node, and configured to transmit the first voltage signal to the third node under control of the first clock signal. The first energy-storing sub-circuit is electrically connected to the first voltage signal terminal and the first node, and configured to maintain the voltage of the first node. The second energy-storing sub-circuit is electrically connected to the second node and the signal output terminal, and configured to maintain the voltage of the second node. The third energy-storing sub-circuit is electrically connected to the third node and the first voltage signal terminal, and configured to maintain a voltage of the third node.

In some embodiments, the reset sub-circuit includes a twenty-second transistor, a control electrode of the twenty-second transistor is electrically connected to the third clock signal terminal, a first electrode of the twenty-second transistor is electrically connected to the first voltage signal terminal, and a second electrode of the twenty-second transistor is electrically connected to the first node. The initialization sub-circuit includes a twenty-third transistor, a control electrode of the twenty-third transistor is electrically connected to the first clock signal terminal, a first electrode of the twenty-third transistor is electrically connected to the first voltage signal terminal, and a second electrode of the twenty-third transistor is electrically connected to the third node. The first energy-storing sub-circuit includes a first capacitor, a plate of the first capacitor is electrically connected to the first voltage signal terminal, and the other plate of the first capacitor is electrically connected to the first node. The second energy-storing sub-circuit includes a second capacitor, a plate of the second capacitor is electrically connected to the second node, and the other plate of the second capacitor is electrically connected to the signal output terminal. The third energy-storing sub-circuit includes a third capacitor, a plate of the third capacitor is electrically connected to the first voltage signal terminal, and the other plate of the third capacitor is electrically connected to the third node.

In another aspect, a driving method of a shift register is provided, which is used to drive the shift register according to any one of the above embodiments. A display period includes a selection phase and an output phase. In the case where the shift register is selected not to output a scanning signal, the driving method includes: in the selection phase, at least one selection control signal terminal of the plurality of selection control signal terminals outputting an operating voltage, the first decode sub-circuit transmitting the operating voltage to the third node, the third control sub-circuit transmitting the first voltage signal to the second node and the third node under control of an operating voltage of the third node; and in the output phase, the second output sub-circuit being turned off under control of the first voltage signal of the second node and outputting no scanning signal. In the case where the shift register is selected to output a scanning signal, the driving method includes: in the selection phase, the plurality of selection control signal terminals all transmitting a non-operating voltage, and the first control sub-circuit and the second control sub-circuit transmitting the second clock signal from the second clock signal terminal to the second node; and in the output phase, the second output sub-circuit transmitting a third clock signal from the third clock signal terminal to the signal output terminal under control of the voltage of the second node to output the third clock signal.

In some embodiments, the selection phase includes a first phase and a third phase that are arranged in sequence. In the case where the shift register is selected to output no scanning signal, the driving method includes: in the first phase, the first control sub-circuit transmitting the first clock signal to the first node under control of a first clock signal form the first clock signal terminal; and in the third phase, the second control sub-circuit transmitting the second clock signal to the second node under control of the second clock signal from the second clock signal terminal and the first clock signal from the first node.

In some embodiments, the shift register further includes a second decode sub-circuit, the display period further includes a black frame insertion phase located after the output phase, and the driving method further includes: in the black frame insertion phase, the second decode sub-circuit transmitting a second voltage signal from the second voltage signal terminal to the signal output terminal under control of a black frame insertion control signal from at least one black frame insertion control signal terminal and a first control signal from a first control signal terminal.

In some embodiments, the shift register includes a black frame insertion control sub-circuit, the display period further includes a black frame insertion phase located after the output phase, and the driving method further includes: in the black frame insertion phase, the first decode sub-circuit transmitting a second voltage signal to a fifth node under control of at least one selection control signal, and the black frame insertion control sub-circuit transmitting a voltage of the fifth node to the signal output terminal under control of a first control signal from a first control signal terminal.

In another aspect, a gate driving circuit is provided. The gate driving circuit includes a plurality of the shift registers each according to any one of the above embodiments and a plurality of groups of selection control signal lines. Each group of selection control signal lines includes two selection control signal lines, and each selection control signal line forms a selection control signal terminal; a first decode sub-circuit of a shift register is electrically connected to a selection control signal line in each group of selection control signal lines, and the selection control signal line forms a selection control signal terminal.

In some embodiments, every four shift registers constitute a shift register group, and the four shift registers included in the shift register group are sequentially arranged as a first-stage shift register, a second-stage shift register, a third-stage shift register and a fourth-stage shift register. The gate driving circuit further includes a first clock signal line, a second clock signal line, a third clock signal line and a fourth clock signal line. The first clock signal line is electrically connected to a first clock signal terminal of the first-stage shift register, a third clock signal terminal of the second-stage shift register, and a second clock signal terminal of the third-stage shift register. The second clock signal line is electrically connected to a first clock signal terminal of the second-stage shift register, a third clock signal terminal of the third-stage shift register, and a second clock signal terminal of the fourth-stage shift register. The third clock signal line is electrically connected to a second clock signal terminal of the first-stage shift register, a first clock signal terminal of the third-stage shift register, and a third clock signal terminal of the fourth-stage shift register. The fourth clock signal line is electrically connected to a third clock signal terminal of the first-stage shift register, a second clock signal terminal of the second-stage shift register, and a first clock signal terminal of the fourth-stage shift register.

In some embodiments, one of the two selection control signal lines of each group of selection control signal lines transmits an operating voltage, and the other one of the two selection control signal lines of each group of selection control signal lines transmits a non-operating voltage. The first clock signal line, the second clock signal line, the third clock signal line and the fourth clock signal line sequentially transmit the operating voltage.

In some embodiments, the shift register includes a second decode sub-circuit, the second decode sub-circuit is electrically connected to a selection control signal line of each group of selection control signal lines, and a selection control signal line forms a black frame insertion control signal terminal. The second decode sub-circuit and the first decode sub-circuit are electrically connected to a same selection control signal line or different selection control signal lines in a same group of selection control signal lines.

In another aspect, a display device is provided. The display device includes the shift register according to any one of the above embodiments or the gate driving circuit according to any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly below. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments;

FIG. 2 is a structural diagram of another display device, in accordance with some embodiments;

FIG. 3 is an equivalent circuit diagram of a pixel circuit, in accordance with some embodiments;

FIG. 4A is a control timing diagram of a pixel circuit, in accordance with some embodiments;

FIG. 4B is a control timing diagram of another pixel circuit, in accordance with some embodiments;

FIG. 5 is a structural diagram of a gate driving circuit, in accordance with some embodiments;

FIG. 6 is a structural diagram of a shift register, in accordance with some embodiments;

FIG. 7 is an equivalent circuit diagram of a first decode sub-circuit, in accordance with some embodiments;

FIG. 8 is an equivalent circuit diagram of another first decode sub-circuit, in accordance with some embodiments;

FIG. 9A is an equivalent circuit diagram of a shift register, in accordance with some embodiments;

FIG. 9B is an equivalent circuit diagram of another shift register, in accordance with some embodiments;

FIG. 10 is a structural diagram of another shift register, in accordance with some embodiments;

FIG. 11 is an equivalent circuit diagram of another shift register, in accordance with some embodiments;

FIG. 12 is an equivalent circuit diagram of yet another shift register, in accordance with some embodiments;

FIG. 13 is a structural diagram of yet another shift register, in accordance with some embodiments;

FIG. 14 is an equivalent circuit diagram of yet another shift register, in accordance with some embodiments;

FIG. 15 is a structural diagram of yet another shift register, in accordance with some embodiments;

FIG. 16 is an equivalent circuit diagram of yet another shift register, in accordance with some embodiments;

FIG. 17 is another structural diagram of a shift register, in accordance with some embodiments;

FIG. 18 is an equivalent circuit diagram of yet another shift register, in accordance with some embodiments;

FIG. 19 is an equivalent circuit diagram of yet another shift register, in accordance with some embodiments;

FIG. 20 is an equivalent circuit diagram of yet another shift register, in accordance with some embodiments;

FIG. 21 is an equivalent circuit diagram of yet another shift register, in accordance with some embodiments;

FIG. 22 is an equivalent circuit diagram of yet another shift register, in accordance with some embodiments;

FIG. 23 is a control timing diagram of a shift register, in accordance with some embodiments; and

FIG. 24 is a control timing diagram of another shift register, in accordance with some embodiments.

### DESCRIPTION OF THE INVENTION

The technical solutions in some embodiments of the present disclosure will be described clearly and completely below in conjunction with the accompanying drawings. Obviously, the embodiments to be described are merely some but not all embodiments of the present disclosure. All other embodiments obtained by a person of ordinary skill in the art based on embodiments of the present disclosure should be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “including, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

Some embodiments may be described using the term “connected” and its derivatives. The term “connected” should be understood in a broad sense. For example, “connected” may represent a fixed connection, a detachable connection, or a one-piece connection; it may represent a direct connection, or an indirect connection through an intermediate medium. For example, the term “connected” may be used when describing some embodiments to indicate that two or more components are in direct physical or electrical contact with each other.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” used herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value, and the acceptable range of deviation is determined by a person of ordinary skill in the art, considering measurement in question and errors (i.e., limitations of a measurement system) associated with measurement of a particular quantity.

The term such as “parallel”, “perpendicular” or “equal” as used herein includes a stated case and a case similar to the stated case within an acceptable range of deviation, and the acceptable range of deviation is determined by a person of ordinary skill in the art, considering measurement in question and errors (i.e., limitations of a measurement system) associated with measurement of a particular quantity. For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

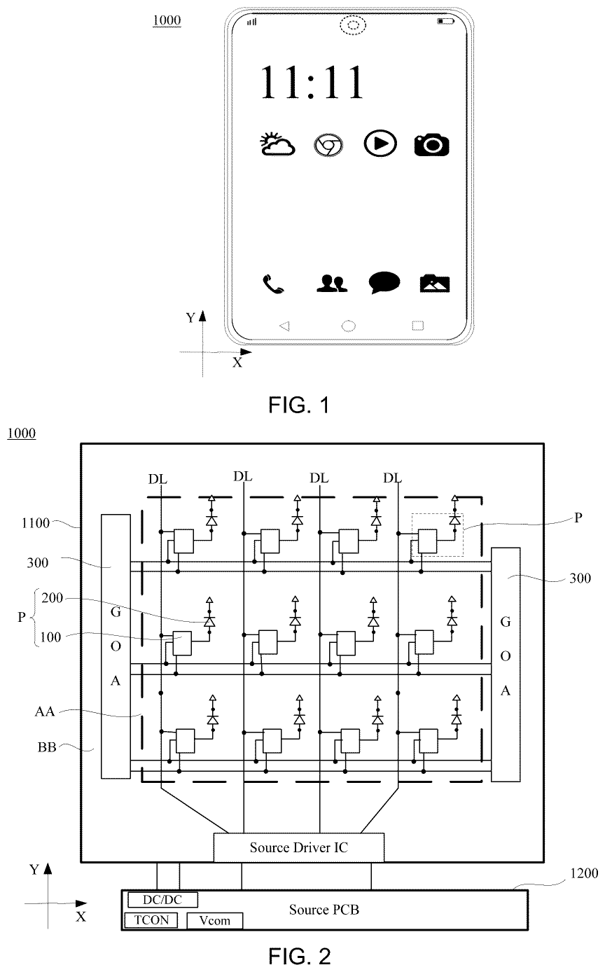

FIG. 1 is an overall structural diagram of a display device, in accordance with some embodiments.

Referring to FIG. 1, embodiments of the present disclosure provide a display device 1000, and the display device 1000 is a product having an image display function. For example, the display device 1000 may be any device that displays images whether in motion (e.g., videos) or stationary (e.g., static images), and whether textual or graphical.

For example, the display device 1000 may be any product or component that has a display function, such as a television, a notebook computer, a tablet computer, a personal digital assistant (PDA), a mobile phone, a watch, a clock, a calculator, a GPS receiver/navigator, a camera, a monitor (e.g., a monitor of a rear camera in a vehicle) in a camera view, a wearable device, an augmented reality (AR) device, a virtual reality (VR) device, a vehicle-mounted display, or a flight display. For example, as shown in FIG. 1, the display device 1000 may be a mobile phone.

The display device 1000 may be an organic light-emitting diode display device, a quantum dot light-emitting diode (QLED) display device or a mini/micro light-emitting diode (MLED) display device from the perspective of the light-emitting type of the display device 1000, the display device 1000 may be a plane display device, a curved display device, or a foldable display device from the perspective of the form of the display device 1000, the display device 1000 may have a rectangular or circular shape from the perspective of the shape of the display device 1000, and the embodiments of the present disclosure do not specifically limit thereto. Some embodiments of the present disclosure will be schematically described below by taking an example in which the display device is a rectangular plane organic light-emitting diode display device, but the embodiments of the present disclosure are not limited thereto, and any other display devices may also be taken into consideration as long as the same technical concept is applied.

FIG. 2 is a structural diagram of a display device in accordance with some other embodiments.

In some embodiments, the display device 1000 includes a display panel 1100 and a driving circuit board 1200. The driving circuit board 1200 may include driving circuits such as a timing controller (TCON), a power supply management chip DC/DC, and an adjustable resistor voltage divider circuit (for generating Vcom). The driving circuit board 1200 may further include other circuit structures, which are not listed here one by one. The driving circuit board 1200 is electrically connected to the display panel 1100 and is used to transmit control signals to the display panel 1100, thereby driving the display panel 1100 to achieve image display. In addition, the display device 1000 may further include a touch structure, an under-display camera and an under-display fingerprint recognition sensor, so that the display device 1000 can realize various different functions such as touching, photographing, video recording, fingerprint recognition and face recognition, which are not specifically limited here.

With continued reference to FIG. 2, the display panel 1100 has a display area AA and a peripheral area BB. The peripheral area BB is located on at least one side of the display area AA. For example, the peripheral area BB is disposed surrounding the display area AA. The display area AA refers to an area of the display panel 1100 for displaying images. The display area AA is provided with a plurality of sub-pixels P therein. The sub-pixel P is the smallest light-emitting unit in the display panel 1100 and is used to display images.

The plurality of sub-pixels P may emit light of a same color, such as white light or blue light. In this case, the display panel further includes a color filter layer disposed on a display side, which means that a color filter (CF) on encapsulation (COE) structure is adopted in the display panel. Alternatively, the plurality of sub-pixels P may emit light of different colors. For example, the plurality of sub-pixels P include red sub-pixels that emit red light, green sub-pixels that emit green light, and blue sub-pixels that emit blue light.

The plurality of sub-pixels P are arranged in multiple rows and multiple columns, each row includes sub-pixels P arranged in a first direction X, and the multiple rows of sub-pixels P are arranged in a second direction Y. Each column includes sub-pixels P arranged in a second direction Y and the multiple columns of sub-pixels P are arranged in the first direction X. The first direction X intersects with the second direction Y; for example, the first direction X is perpendicular to the second direction Y. A row of sub-pixels P arranged in the first direction X is also referred to as a pixel row.

As shown in FIG. 2, the display panel 1100 further includes a plurality of data lines DL. The plurality of data lines DL are arranged at intervals in the first direction X, and the plurality of data lines DL all extend in the second direction Y. Each data line DL may be electrically connected to a column of sub-pixels P, and a data line DL is configured to transmit a data signal to a column of sub-pixels P that are electrically connected to the data line DL.

Each sub-pixel P includes a pixel circuit 100 and a light-emitting device 200. The pixel circuit 100 includes a plurality of thin film transistors (TFTs) and at least one capacitor Cst. For example, the pixel circuit 100 may be a “3T1C” circuit, a “7T1C” circuit, or an “8T1C” circuit, and the embodiments of the present disclosure are not limited thereto; any other pixel circuits may also be taken into consideration as long as the same technical concept is applied. Here, “T” represents a thin film transistor, the number before “T” represents the number of the thin film transistors; “C” represents a capacitor Cst, and the number before “C” represents the number of capacitors Cst.

In some embodiments, the thin film transistor may be an oxide thin film transistor. Oxide thin film transistors have become the first choice for large-size, high-resolution, low-power consumption, and narrow-bezel display panels due to their advantages such as high electron mobility, low off-state current, and simple manufacturing process. A pixel circuit formed based on the oxide thin film transistors needs to be externally compensated to allow the pixel circuit to drive the light-emitting device to display a required gray scale.

In the embodiments of the present disclosure, each transistor includes a gate, a source and a drain. The connection manners of the source and drain of the transistor are interchangeable, so there is actually no difference between the source and drain of each transistor in the embodiments of the present disclosure. Here, it is only to distinguish the two electrodes of the transistor except for the control electrode (i.e., the gate), one of which is referred to as the drain and the other is referred to as the source. The transistor adopted in the embodiments of the present disclosure may be an N-type transistor or a P-type transistor. In a case where the transistor adopted in the embodiments of the present disclosure is an N-type transistor, a first electrode of the transistor is the source, and a second electrode of the transistor is the drain. In a case where the transistor adopted in the embodiments of the present disclosure is a P-type transistor, a first electrode of the transistor is the drain, and a second electrode of the transistor is the source. In the following embodiments, the N-type transistor is used as an example for description, and the transistor is turned on when the signal received by the control electrode is a high voltage. It will be understood that in a case where the transistor adopted in the embodiments of the present application is a P-type transistor, the timing change of the driving signal needs to be adjusted accordingly; the specific details will not be elaborated here, but also fall within the protection scope of the present application.

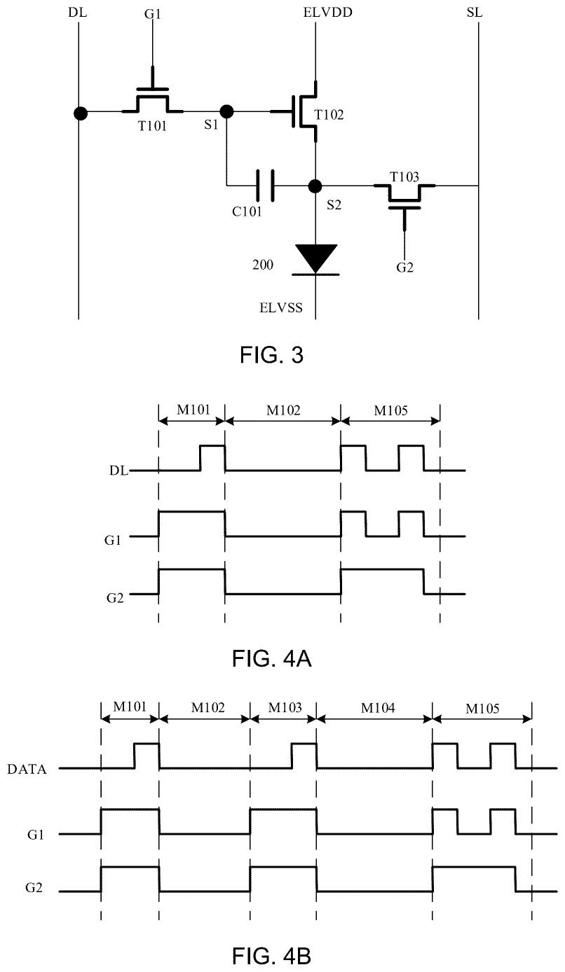

FIG. 3 is an equivalent circuit diagram of a pixel circuit 100, in accordance with some embodiments.

Referring to FIG. 3, in some embodiments, the pixel circuit 100 may be a “3T1C circuit”. The pixel circuit 100 includes a data writing transistor T101, a driving transistor T102, a sensing transistor T103 and a storage capacitor C101. A control electrode of the data writing transistor T101 is electrically connected to a first scanning signal terminal G1. The first scanning signal terminal G1 may be electrically connected to a shift register of a gate driving circuit through a scanning signal line (not shown in the figure). A first electrode of the data writing transistor T101 is electrically connected to a data line DL to receive data signals provided by the data line DL. The data signals may include a display data signal, a sensing data signal and a black frame insertion data signal. A second electrode of the data writing transistor T101 is electrically connected to a first circuit node S1. A control electrode of the driving transistor T102 is electrically connected to the first circuit node S1; that is, the control electrode of the driving transistor T102 is electrically connected to the second electrode of the data writing transistor T101. A first electrode of the driving transistor T102 is electrically connected to a first power supply voltage terminal ELVDD; for example, the first power supply voltage terminal ELVDD is used to provide a high voltage signal. A second electrode of the driving transistor T102 is connected to a second circuit node S2. One plate of the storage capacitor C101 is electrically connected to the first circuit node S1, and the other plate of the storage capacitor C101 is electrically connected to the second circuit node S2. In other words, one plate of the storage capacitor C101 is electrically connected to the second electrode of the data writing transistor T101 and the control electrode of the driving transistor T102, and the other plate is electrically connected to the second electrode of the driving transistor T102. A control electrode of the sensing transistor T103 is electrically connected to a second scanning signal terminal G2, a first electrode of the sensing transistor T103 is electrically connected to the second circuit node S2, and a second electrode of the sensing transistor T103 is electrically connected to a sensing signal line SL. A terminal (an anode terminal) of the light-emitting device 200 is electrically connected to the second circuit node S2, and the other terminal (a cathode terminal) of the light-emitting device 200 is electrically connected to a second power supply voltage terminal ELVSS. For example, the second power supply voltage terminal ELVSS is used to provide a low voltage signal.

FIG. 4A is a driving timing diagram of the pixel circuit 100 shown in FIG. 3, which includes a display phase and a sensing phase.

Referring to FIGS. 3 and 4A, a display period of the pixel circuit 100 may include three phases: a display data writing phase M101, a light-emitting phase M102, and a sensing phase M105.

In the display data writing phase M101, the first scanning signal terminal G1 and the second scanning signal terminal G2 output a high voltage, the data writing transistor T101 and the sensing transistor T103 are turned on, and the data writing transistor T101 transmits a display data signal transmitted by the data line DL to the first circuit node S1.

It will be understood that, in the embodiments of the present disclosure, the “first circuit node” in the pixel circuit and the “first node” and “second node” in the shift register below do not represent actual existing components, but represent junctions of related electrical connections in the circuit diagram, which means, these nodes are nodes equivalent to confluence points of related electrical connections in the circuit diagram.

In the light-emitting phase M102, the first scanning signal terminal G1 and the second scanning signal terminal G2 output a low voltage, and the data writing transistor T101 and the sensing transistor T103 are turned off. A bootstrap effect occurs for the storage capacitor C101, and the voltage (the display data signal) of the first circuit node S1 remains unchanged due to the action of the storage capacitor C101; the driving transistor T102 is turned on under the control of the display data signal to drive the light-emitting device 200 to emit light.

In the sensing phase M105, firstly, the first scanning signal terminal G1 and the second scanning signal terminal G2 output a high voltage, the data line DL transmits a sensing data signal, the data writing transistor T101 and the sensing transistor T103 are turned on, and the data writing transistor T101 transmits the sensing data signal transmitted by the data line DL to the first circuit node S1. Subsequently, the first scanning signal terminal G1 outputs a low voltage, the data writing transistor T101 is turned off; the second scanning signal terminal G2 continues to output a high voltage, and the sensing transistor T103 remains on. The driving transistor T102 is turned on, and the second electrode of the sensing transistor T103 outputs a pixel compensation signal to achieve a compensation function for the pixel circuit. Then, the first scanning signal terminal G1 and the second scanning signal terminal G2 output a high voltage, the data line DL transmits a black frame insertion data signal, the data writing transistor T101 and the sensing transistor T103 are turned on, the data writing transistor T101 transmits the black frame insertion data signal to the first circuit node S1, and the driving transistor T102 is turned off. The black frame insertion data signal may be, for example, a 0 gray scale signal, so as to clear the sensing data signal stored in the storage capacitor C101. Finally, the first scanning signal terminal G1 and the second scanning signal terminal G2 output a low voltage, and the data writing transistor T101 and the sensing transistor T103 are turned off.

As shown in FIG. 2, the peripheral area BB may be used to be provided with, for example, a gate driving circuit 300 and control signal lines (e.g., clock signal lines and power supply voltage signal lines). Of course, the functions of the peripheral area BB are not limited this, and the embodiments of the present disclosure will not describe them one by one.

In the related art, a gate driving circuit includes a plurality of shift registers, and the plurality of shift registers are cascaded in sequence. Based on this, the gate driving circuit may scan multiple rows of sub-pixels row by row (driving by means of row-by-row) in the second direction. In this way, when a display device performs a local high-frequency (refresh frequency) display or detects part of the rows, it is also needed to scan row by row starting from the first row, which is not conducive to reducing the power consumption of the display panel.

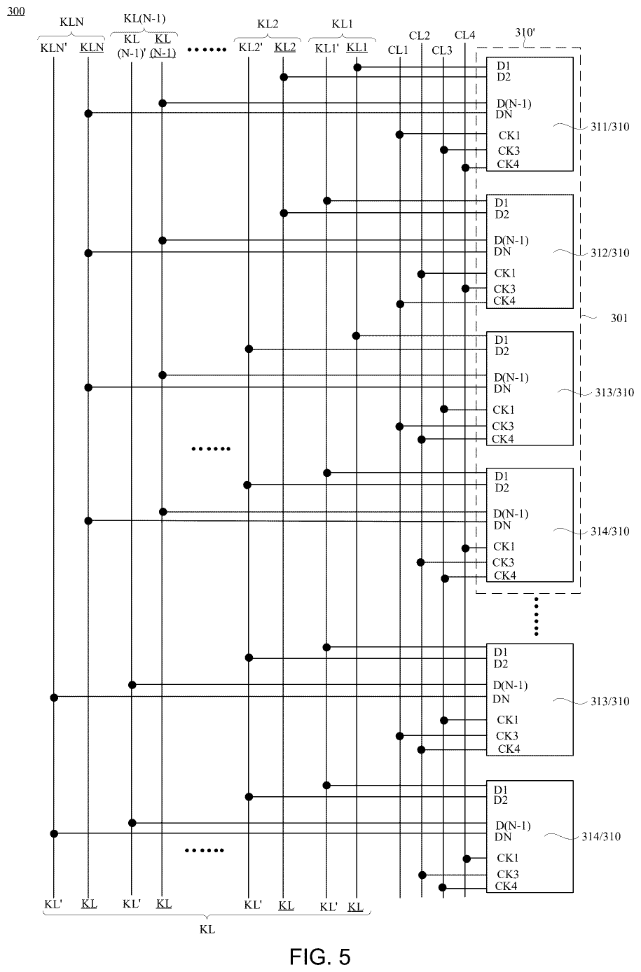

FIG. 5 is a structural diagram of a gate driving circuit, in accordance with some embodiments.

Referring to FIG. 5, in order to solve the above technical problem, embodiments of the present disclosure provide a gate driving circuit 300. The gate driving circuit 300 includes a plurality of shift registers 310. Each shift register 310 is configured to be electrically connected to pixel circuits of a row of sub-pixels, and output a scanning signal to the row of sub-pixels electrically connected to the shift register 310 to perform scanning driving on the row of sub-pixels.

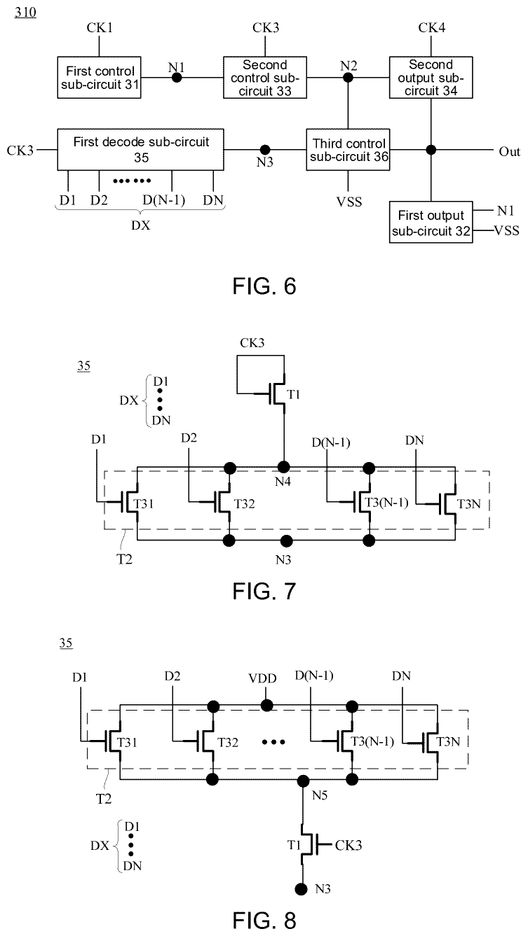

FIG. 6 is a structural diagram of a shift register, in accordance with some embodiments.

Referring to FIG. 6, some embodiments of the present disclosure provide a shift register 310. The shift register 310 includes a first control sub-circuit 31, a first output sub-circuit 32, a second control sub-circuit 33, a second output sub-circuit 34, a first decode sub-circuit 35 and a third control sub-circuit 36.

As shown in FIG. 6, the first control sub-circuit 31 is electrically connected to a first clock signal terminal CK1 and a first node N1. The first control sub-circuit 31 is configured to transmit the first clock signal to the first node N1 under control of a first clock signal from the first clock signal terminal CK1. The first output sub-circuit 32 is electrically connected to the first node N1, a first voltage signal terminal VSS and a signal output terminal Out. The first output sub-circuit 32 is configured to transmit a first voltage signal from the first voltage signal terminal VSS to the signal output terminal Out under control of a voltage of the first node N1. The first voltage signal terminal VSS is used to transmit the first voltage signal, and the first voltage signal may be, for example, a low voltage signal.

For example, in a case where the first clock signal terminal CK1 transmits the first clock signal, the first control sub-circuit 31 transmits the first clock signal transmitted by the first clock signal terminal CK1 to the first node N1, and the first output sub-circuit 32, under the control of the first clock signal of the first node N1, outputs a low voltage signal of the first voltage signal terminal VSS from the signal output terminal Out (without outputting a scanning signal).

The second control sub-circuit 33 is electrically connected to the first node N1, a second clock signal terminal CK3 and a second node N2. The second control sub-circuit 33 is configured to, under control of a voltage of a second clock signal from the second clock signal terminal CK3 and a voltage of the first node N1, transmit the second clock signal to the second node N2. The second output sub-circuit 34 is electrically connected to the second node N2, a third clock signal terminal CK4 and the signal output terminal Out. The second output sub-circuit 34 is configured to, under control of a voltage of the second node N2, transmit a third clock signal from the third clock signal terminal CK4 to the signal output terminal Out.

For example, in a case where the first control sub-circuit 31 transmits the first clock signal to the first node N1, and the second clock signal terminal CK3 outputs the second clock signal, the second control sub-circuit 33, under the control of the first clock signal of the first node N1 and the second clock signal, transmits the second clock signal to the second node N2. The second output sub-circuit 34, under the control of the voltage of the second node N2 (the second clock signal), transmits the third clock signal to the signal output terminal Out, and the signal output terminal Out outputs a scanning signal.

The first decode sub-circuit 35 is electrically connected to a plurality of selection control signal terminals DX, the second clock signal terminal CK3 and a third node N3. For example, as shown in FIG. 6, the first decode sub-circuit 35 is electrically connected to N selection control signal terminals DX, where N is a positive integer greater than 0, and the N selection control signal terminals DX are sequentially arranged as a first selection control signal terminal D1, a second selection control signal terminal D2, . . . , an (N-1)-th selection control signal terminal D(N-1) and an N-th selection control signal terminal DN.

The first decode sub-circuit 35 is configured to, under control of an operating voltage from at least one selection control signal terminal DX and the second clock signal from the second clock signal terminal CK3, select the shift register 310 to output no scanning signal. Alternatively, the first decode sub-circuit 35 is configured to, under control of a non-operating voltage of each selection control signal terminal DX of the plurality of selection control signal terminals DX and the second clock signal from the second clock signal terminal CK3, select the shift register 310 to output a scanning signal.

It will be understood that, in the embodiments of the present disclosure, all the transistors included in the pixel circuits and the gate driving circuit are N-type transistors as examples. The operating voltage refers to a voltage at which the N-type transistor is turned on; that is, the operating voltage refers to a high voltage. On the contrary, the non-operating voltage refers to a voltage at which the N-type transistor is turned off; that is, the non-operating voltage refers to a low voltage. Furthermore, the scanning signal refers to a voltage at which a transistor (the data writing transistor T101) is turned on; that is, the scanning signal refers to a high voltage signal. In a case where the voltage of the signal output terminal Out is the first voltage signal provided by the first voltage signal terminal VSS, it is considered that the signal output terminal Out does not output a scanning signal.

The third control sub-circuit 36 is electrically connected to the first voltage signal terminal VSS, the second node N2, the third node N3 and the signal output terminal Out. The third control sub-circuit 36 is configured to: in a case where the shift register 310 is selected to output no scanning signal, transmit the first voltage signal from the first voltage signal terminal VSS to the second node N2 and the signal output terminal Out; and in a case where the shift register 310 is selected to output the scanning signal, transmit the first voltage signal from the first voltage signal terminal VSS to the third node N3.

For example, at least one selection control signal terminal DX transmits an operating voltage, and the second clock signal terminal CK3 transmits a second clock signal, the first decode sub-circuit 35 transmits an operating voltage to the third node N3, and the third control sub-circuit 36 transmits the first voltage signal from the first voltage signal terminal VSS to the second node N2 and the signal output terminal Out under the control of the operating voltage of the third node N3. In this case, the signal output terminal Out does not output a scanning signal.

For example, each selection control signal terminal DX of the plurality of selection control signal terminals DX transmits a non-operating voltage, and the second clock signal terminal CK3 transmits the second clock signal or does not transmit the second clock signal, the first decode sub-circuit 35 does not transmit any voltage signal to the third node N3, and the third control sub-circuit 36 transmits the first voltage signal of the first voltage signal terminal VSS to the third node N3 under the control of the voltage of the second node N2. The third control sub-circuit 36 disconnects the first voltage signal terminal VSS from the signal output terminal Out under the control of the first voltage signal (the non-operating voltage) of the third node N3, and enables the signal output terminal Out to output a scanning signal under the control of the second control sub-circuit 33 and the second output sub-circuit 34.

As shown in FIG. 5, the gate driving circuit 300 further includes a plurality of groups of selection control signal lines KL. Each group of selection control signal lines KL includes two selection control signal lines KL. For example, two selection control signal lines KL in a group are respectively denoted as a first selection control signal line KL′ and a second selection control signal line KL. The first decode sub-circuit 35 of the shift register 310 is electrically connected to one selection control signal line KL in each group of selection control signal lines KL. Specifically, it may be that each selection control signal terminal DX is electrically connected to a selection control signal line KL in a group of selection control signal lines KL, so that a selection control signal line KL forms a selection control signal terminal DX.

In some embodiments, a first selection control signal line KL′ and a second selection control signal line KL in a group transmit completely opposite voltage signals. For example, the first selection control signal line KL′ transmits an operating voltage, and the second selection control signal line KL transmits a non-operating voltage; alternatively, the first selection control signal line KL′ transmits a non-operating voltage, and the second selection control signal line KL transmits an operating voltage. Based on this, two first decode sub-circuits respectively connected to the first selection control signal line KL′ and the second selection control signal line KL may have different compilation states.

For example, the plurality of groups of selection control signal lines KL are in one-to-one correspondence with the plurality of selection control signal terminals DX connected to the first decode sub-circuit 35. The display panel includes N groups of selection control signal lines KL, and the N groups of selection control signal lines KL are sequentially numbered as a first group of selection control signal lines KL1, a second group of selection control signal lines KL2, . . . , an (N-1)-th group of selection control signal lines KL(N-1) and an N-th group of selection control signal lines KLN. The first selection control signal terminal D1 connected to the first decode sub-circuit 35 is electrically connected to one of a first group first selection control signal line KL1′ and a first group second selection control signal line KL1 that are included in the first group of selection control signal lines KL1. For example, the first selection control signal terminal D1 is electrically connected to the first group first selection control signal line KL1′, and in this case, the first group first selection control signal line KL1′ forms the first selection control signal terminal D1.

It will be understood that the multiple selection control signal terminals DX connected to at least two shift registers 310 are not completely the same. For example, there are 2^{N} (2 to the power of N) different connection modes between the selection control signal terminals DX connected to the shift register 310 and the plurality of groups of selection control signal lines KL, so that the shift register 310 may compile 2^{N} different states. Moreover, only in one compilation state (the selection control signal lines KL connected to the plurality of selection control signal terminals DX of the shift register 310 simultaneously transmit the non-operating voltage), the shift register 310 may be selected to output a scanning signal. Based on this, it is possible to select one of the 2^{N} shift registers 310 to output a scanning signal through the N groups of selection control signal lines KL, while the other (2^{N}−1) shift registers 310 do not output a scanning signal.

In an example, the value of N may be 10, and the display panel includes 10 groups of selection control signal lines KL; that is, the display panel includes 20 selection control signal lines KL. There are 2¹⁰ different connection modes between the 10 selection control signal terminals DX electrically connected to the shift register 310 and the 10 groups of selection control signal lines KL. Each selection control signal line KL transmitting an operating voltage is labeled as “1”, and transmitting a non-operating voltage is labeled as “0”, and each selection control signal terminal DX of the 10 selection control signal terminals DX may receive two voltages of 1 or 0. In this way, the shift register 310 may receive 2^{N} different voltage combinations; that is, 2^{N} different states are compiled, for example, 0000000000, 0000000001, 0000000010, 0000000011, 000000100, . . . , 1111111110, 1111111111. Only when the shift register 310 receives the voltage combination of 0000000000, the shift register 310 is selected to output a scanning signal.

In summary, in the gate driving circuit 300 provided by the embodiments of the present disclosure, as shown in FIG. 5, each shift register 310 of the plurality of shift registers 310 is directly electrically connected to the plurality of groups of selection control signal lines KL, and the plurality of shift registers 310 may not be cascaded, and any shift register 310 may be selected to output a scanning signal through the plurality of groups of selection control signal lines KL. Based on this, the gate driving circuit 300 may arbitrarily adjust the order in which the plurality of shift registers 310 output the scanning signal (e.g., not scanning in a row-by-row order) and the scanning frequency of different shift registers 310. In this way, it is possible to arbitrarily select a specific row of sub-pixels and a specific scanning order to perform scanning driving on a row or multiple rows of sub-pixels according to display requirements (e.g., detecting a specific row of sub-pixels, or performing locally high-frequency refresh display), which is conducive to reducing the power consumption of the display panel.

FIG. 7 is an equivalent circuit diagram of a first decode sub-circuit, in accordance with some embodiments. Referring to FIG. 7, in some embodiments, the first decode sub-circuit 35 includes a first transistor T1 and a plurality of second transistors T2. A control electrode and a first electrode of the first transistor T1 are both electrically connected to the second clock signal terminal CK3, and a second electrode of the first transistor T1 is electrically connected to a fourth node N4. A control electrode of each second transistor T2 is electrically connected to a selection control signal terminal DX, first electrodes of the plurality of second transistors T2 are electrically connected to the fourth node N4, and second electrodes of the plurality of second transistors T2 are electrically connected to the third node N3.

For example, the plurality of second transistors T2 are sequentially denoted as a first selection transistor T31, a second selection transistor T32, . . . , an (N-1)-th selection transistor T3(N-1) and an N-th selection transistor T3N. A control electrode of the first selection transistor T31 is electrically connected to the first selection control signal terminal D1, and the first selection control signal terminal D1 is electrically connected to one of the first group first selection control signal line KL1′ and the first group second selection control signal line KL1 included in the first group of selection control signal lines KL1, that is, the control electrode of the first selection transistor T31 is electrically connected to the first group first selection control signal line KL1′ or the first group second selection control signal line KL1. A control electrode of the second selection transistor T32 is electrically connected to the second selection control signal terminal D2, and is electrically connected to a second group first selection control signal line KL2′ or a second group second selection control signal line KL2; . . . ; a control electrode of the N-th selection transistor T3N is electrically connected to the N-th selection control signal terminal DN, and is electrically connected to an N-th group first selection control signal line KLN′ or an N-th group second selection control signal line KLN.

In a case where the second clock signal terminal CK3 transmits a second clock signal (the operating voltage), the first transistor T1 is turned on, and the first transistor T1 transmits the second clock signal transmitted by the second clock signal terminal CK3 to the fourth node N4. Meanwhile, in a case where at least one of the plurality of selection control signal terminals DX transmits an operating voltage (a high voltage), a second transistor T2 in the plurality of second transistors T2 that is connected to a selection control signal terminal DX transmitting the operating voltage is turned on and transmits the second clock signal received by the fourth node N4 to the third node N3. For example, the first selection control signal terminal D1 transmits the operating voltage, the first selection transistor T31 electrically connected to the first selection control signal terminal D1 is turned on, and the first selection transistor T31 transmits the second clock signal received by the fourth node N4 to the third node N3. In this case, the shift register 310 is selected to output no scanning signal.

Alternatively, in a case where the second clock signal terminal CK3 transmits the second clock signal, the first transistor T1 is turned on, and the first transistor T1 transmits the second clock signal transmitted by the second clock signal terminal CK3 to the fourth node N4. Meanwhile, the plurality of selection control signal terminals DX all transmit the non-operating voltage (a low voltage), the plurality of second transistors T2 are all in an off state, and the second clock signal received by the fourth node N4 will not be transmitted to the third node N3. That is, the first decode sub-circuit 35 does not transmit the operating voltage signal to the third node N3. In this case, the shift register 310 is selected to output a scanning signal.

FIG. 8 is an equivalent circuit diagram of a first decode sub-circuit, in accordance with some embodiments.

In some other embodiments, referring to FIG. 8, the first decode sub-circuit 35 is further electrically connected to a second voltage signal terminal VDD. The second voltage signal terminal VDD is used to transmit a second power supply voltage signal, and the second power supply voltage signal may be, for example, a high voltage. The first decode sub-circuit 35 includes a first transistor T1 and a plurality of second transistors T2. A control electrode of the first transistor T1 is electrically connected to the second clock signal terminal CK3, a first electrode of the first transistor T1 is electrically connected to a fifth node N5, and a second electrode of the first transistor T1 is electrically connected to the third node N3. In the plurality of second transistors T2, a control electrode of each second transistor T2 is electrically connected to a selection control signal terminal DX, first electrodes of the plurality of second transistors T2 are all electrically connected to the second voltage signal terminal VDD, and second electrodes of the plurality of second transistors T2 are all electrically connected to the fifth node N5.

For example, the plurality of second transistors T2 are sequentially denoted as a first selection transistor T31, a second selection transistor T32, . . . , an (N-1)-th selection transistor T3(N-1) and an N-th selection transistor T3N. A control electrode of the first selection transistor T31 is electrically connected to a first selection control signal terminal D1, and the first selection control signal terminal D1 is electrically connected to a first group first selection control signal line KL1′ or a first group second selection control signal line KL1; that is, the control electrode of the first selection transistor T31 is electrically connected to the first group first selection control signal line KL1′ or the first group second selection control signal line KL1. A control electrode of the second selection transistor T32 is electrically connected to a second selection control signal terminal D2, and is electrically connected to a second group first selection control signal line KL2′ or a second group second selection control signal line KL2; . . . ; a control electrode of the N-th selection transistor T3N is electrically connected to an N-th selection control signal terminal DN, and is electrically connected to an N-th group first selection control signal line KLN′ or an N-th group second selection control signal line KLN.

In a case where at least one of the plurality of selection control signal terminals DX transmits an operating voltage (a high voltage), a second transistor T2 in the plurality of second transistors T2 that is electrically connected to the selection control signal terminal DX transmitting the operating voltage is turned on and transmits a second voltage signal transmitted by the second voltage signal terminal VDD to the fifth node N5. For example, the first selection control signal terminal D1 transmits the operating voltage, the first selection transistor T31 electrically connected to the first selection control signal terminal D1 is turned on, and the first selection transistor T31 transmits the second voltage signal to the fifth node N5. Furthermore, in a case where the second clock signal terminal CK3 outputs a second clock signal, the first transistor T1 is turned on, and the first transistor T1 transmits the second voltage signal received by the fifth node N5 to the third node N3. In this case, the shift register 310 is selected to output no scanning signal.

Alternatively, in a case where the plurality of selection control signal terminals DX all transmit the non-operating voltage, the plurality of second transistors T2 are all in an off state, and the second voltage signal transmitted by the second voltage signal terminal VDD is not transmitted to the fifth node N5.

Even if the first transistor T1 is turned on in the case where the second clock signal terminal CK3 transmits the second clock signal, the third node N3 cannot receive the second voltage signal because the fifth node N5 does not receive the second voltage signal. That is, the first decode sub-circuit 35 does not transmit an operating voltage (the second voltage signal) to the third node N3, and the shift register 310 is selected to output no scanning signal.

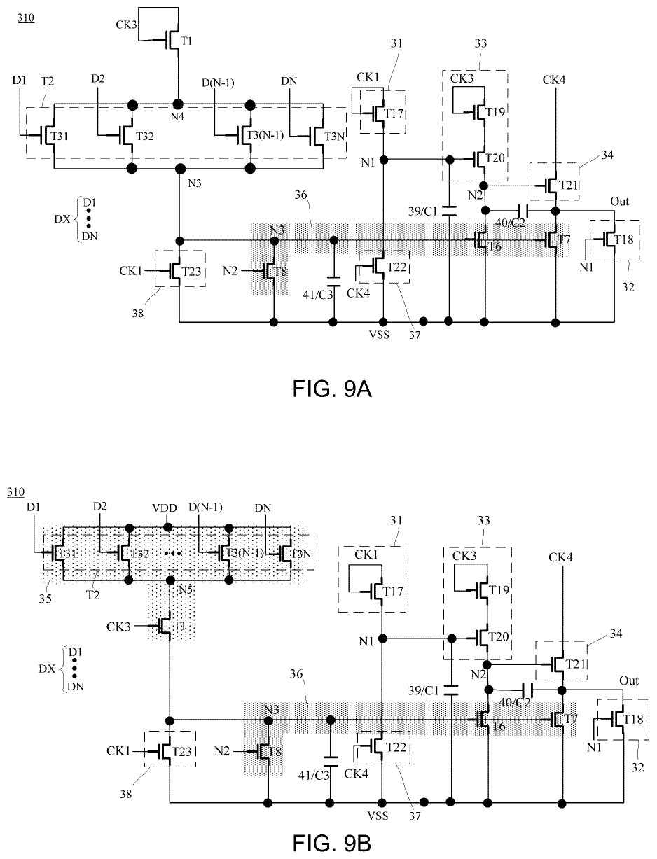

FIG. 9A is an equivalent circuit diagram of a shift register in a case where the first decode sub-circuit has the structure shown in FIG. 7. FIG. 9B is an equivalent circuit diagram of a shift register in a case where the first decode sub-circuit has the structure shown in FIG. 8.

Referring to FIGS. 9A and 9B, in some embodiments, the first control sub-circuit 31 includes a seventeenth transistor T17, a control electrode and a first electrode of the seventeenth transistor T17 are both electrically connected to the first clock signal terminal CK1, and a second electrode of the seventeenth transistor T17 is electrically connected to the first node N1. In a case where the first clock signal terminal CK1 transmits a first clock signal (a high voltage), the seventeenth transistor T17 is turned on and transmits the first clock signal to the first node N1, and the first node N1 is at a high voltage.

In some embodiments, as shown in FIGS. 9A and 9B, the shift register 310 further includes a first energy-storing sub-circuit 39. The first energy-storing sub-circuit 39 is electrically connected to the first voltage signal terminal VSS and the first node N1, and the first energy-storing sub-circuit 39 is configured to maintain the voltage of the first node N1. For example, after the seventeenth transistor T17 transmits the first clock signal to the first node N1 and the seventeenth transistor T17 is turned off, the first energy-storing sub-circuit 39 maintains the voltage of the first node N1 as the first clock signal to reduce the voltage attenuation of the first node N1.

As shown in FIGS. 9A and 9B, the first energy-storing sub-circuit 39 includes a first capacitor C1, one plate of the first capacitor C1 is electrically connected to the first voltage signal terminal VSS, and the other plate of the first capacitor C1 is electrically connected to the first node N1. The first capacitor has a bootstrap effect and can maintain the voltage of the first node N1.

The first output sub-circuit 32 includes an eighteenth transistor T18. A control electrode of the eighteenth transistor T18 is electrically connected to the first node N1, a first electrode of the eighteenth transistor T18 is electrically connected to the first voltage signal terminal VSS, and a second electrode of the eighteenth transistor T18 is electrically connected to the signal output terminal Out. In a case where the first clock signal is transmitted to the first node N1, the eighteenth transistor T18 is turned on under the control of the voltage (the first clock signal) of the first node N1, and the eighteenth transistor T18 transmits the first voltage signal transmitted by the first voltage signal terminal VSS to the signal output terminal Out, and in this case, the shift register 310 does not output a scanning signal.

Referring to FIGS. 9A and 9B, the second control sub-circuit 33 includes a nineteenth transistor T19 and a twentieth transistor T20. A control electrode and a first electrode of the nineteenth transistor T19 are both electrically connected to the second clock signal terminal CK3, and a second electrode of the nineteenth transistor T19 is electrically connected to a first electrode of the twentieth transistor T20. A control electrode of the twentieth transistor T20 is electrically connected to the first node N1, and a second electrode of the twentieth transistor T20 is electrically connected to the second node N2. In a case where the second clock signal terminal CK3 transmits a second clock signal (a high voltage), the nineteenth transistor T19 is turned on, and the nineteenth transistor T19 transmits the second clock signal to the second electrode of the nineteenth transistor T19. Meanwhile, the twentieth transistor T20 is turned on under the control of the voltage of the first node N1, and the twentieth transistor T20 transmits the second clock signal of the second electrode of the nineteenth transistor T19 to the second node N2, and the second node N2 is at a high voltage.

In some embodiments, as shown in FIGS. 9A and 9B, the shift register 310 further includes a second energy-storing sub-circuit 40. The second energy-storing sub-circuit 40 is electrically connected to the signal output terminal Out and the second node N2, and is configured to maintain the voltage of the second node N2. For example, after the nineteenth transistor T19 and the twentieth transistor T20 transmit the second clock signal to the second node N2 and the nineteenth transistor T19 and the twentieth transistor T20 are turned off, the second energy-storing sub-circuit 40 maintains the voltage of the second node N2 as the second clock signal to reduce the voltage attenuation of the second node N2.

As shown in FIGS. 9A and 9B, the second energy-storing sub-circuit 40 includes a second capacitor C2, one plate of the second capacitor C2 is electrically connected to the second node N2, and the other plate of the second capacitor C2 is electrically connected to the signal output terminal Out. The second capacitor C2 has a bootstrap effect to maintain the voltage of the second node N2, and can raise the voltage of the second node N2 in a case where the voltage of the signal output terminal Out increases.

With continued reference to FIGS. 9A and 9B, the second output sub-circuit 34 includes a twenty-first transistor T21. A control electrode of the twenty-first transistor T21 is electrically connected to the second node N2, a first electrode of the twenty-first transistor T21 is electrically connected to the third clock signal terminal CK4, and a second electrode of the twenty-first transistor T21 is electrically connected to the signal output terminal Out. In a case where the second node N2 is at a high voltage, the twenty-first transistor T21 is turned on, and in a case where the third clock signal terminal CK4 transmits a third clock signal, the twenty-first transistor T21 transmits the third clock signal transmitted by third clock signal terminal CK4 to the signal output terminal Out, and the shift register 310 outputs a scanning signal. In a case where the third clock signal is transmitted to the signal output terminal Out, the voltage of the second node N2 is raised due to the bootstrap effect of the second capacitor C2.

With continued reference to FIGS. 9A and 9B, in some embodiments, the third control sub-circuit 36 includes a sixth transistor T6, a seventh transistor T7, and an eighth transistor T8. A control electrode of the sixth transistor T6 is electrically connected to the third node N3, a first electrode of the sixth transistor T6 is electrically connected to the first voltage signal terminal VSS, and a second electrode of the sixth transistor T6 is electrically connected to the second node N2. A control electrode of the seventh transistor T7 is electrically connected to the third node N3, a first electrode of the seventh transistor T7 is electrically connected to the first voltage signal terminal VSS, and a second electrode of the seventh transistor T7 is electrically connected to the signal output terminal Out. A control electrode of the eighth transistor T8 is electrically connected to the second node N2, a first electrode of the eighth transistor T8 is electrically connected to the first voltage signal terminal VSS, and a second electrode of the eighth transistor T8 is electrically connected to the third node N3.

In a case where the shift register 310 is selected not to output a scanning signal, the first decode sub-circuit 35 transmits the second clock signal (as shown in FIG. 9A) or the second voltage signal (as shown in FIG. 9B) to the third node N3, and the voltage of the third node N3 is a high voltage. The sixth transistor T6 is turned on under the control of the high voltage of the third node N3 and transmits the first voltage signal from the first voltage signal terminal VSS to the second node N2. The second output sub-circuit 34 (the twenty-first transistor T21) is in an off state under the control of the first voltage signal of the second node N2. In this case, even if the third clock signal terminal transmits a third clock signal, the signal output terminal Out does not output a scanning signal. The voltage of the second node N2 is kept low, and the eighth transistor T8 is kept off under the control of the voltage of the second node N2. The seventh transistor T7 is turned on under the control of the high voltage of the third node N3, and transmits the first voltage signal from the first voltage signal terminal VSS to the signal output terminal Out, so that the signal output terminal Out continuously outputs a low voltage. In other words, the signal output terminal Out does not output a scanning signal. The eighth transistor T8 remains off under the control of the voltage (the non-operating voltage) of the second node N2, and the voltage of the third node N3 maintains the voltage signal (the second clock signal or the second voltage signal) transmitted to the third node N3 by the first decode sub-circuit 35.

In a case where the shift register 310 is selected to output a scanning signal, the first decode sub-circuit 35 does not transmit any voltage signal to the third node N3, and the voltage of the third node N3 is a low voltage. The sixth transistor T6 is in an off state under the control of the low voltage of the third node N3, which will not affect the voltage of the second node N2. The seventh transistor T7 is in an off state under the control of the low voltage of the third node N3, which will not affect the voltage of the second node N2. Based on this, the seventeenth transistor T17 transmits the first clock signal to the first node N1 under the control of the first clock signal, and the voltage of the first node N1 may maintain the above first clock signal due to action of the first capacitor C1 to enable the twentieth transistor T20 to be turned on. Then, the nineteenth transistor T19 is turned on under the control of the second clock signal, and the second clock signal is transmitted to the second node N2 through the nineteenth transistor T19 and the twentieth transistor T20 in sequence, and the voltage of the second node N2 may maintain the above second clock signal due to the action of the second capacitor C2 to enable the eighth transistor T8 and the twenty-first transistor T21 to be turned on. The eighth transistor T8 is turned on, and transmits the first voltage signal of the first voltage signal terminal VSS to the third node N3, and in this case, the voltage of the third node N3 is kept low. Then, the twenty-first transistor T21 is turned on, and a third clock signal of the third clock signal terminal CK4 may be transmitted to the signal output terminal Out; that is, the shift register 310 outputs a scanning signal. Moreover, due to the bootstrap effect of the second capacitor C2, the voltage of the second node N2 is raised.

With continued reference to FIGS. 9A and 9B, in some embodiments, the shift register 310 further includes a third energy-storing sub-circuit 41. The third energy-storing sub-circuit 41 is electrically connected to the first voltage signal terminal VSS and the third node N3, and is configured to maintain the voltage of the third node N3. For example, after the first decode sub-circuit 35 transmits a second clock signal or a second voltage signal to the third node N3 and the first transistor T1 is turned off, the third energy-storing sub-circuit 41 can maintain the voltage of the third node N3 at a high voltage to reduce the voltage attenuation of the third node N3.

As shown in FIGS. 9A and 9B, the third energy-storing sub-circuit 41 includes a third capacitor C3, one plate of the third capacitor C3 is electrically connected to the third node N3, and the other plate of the third capacitor C3 is electrically connected to the first voltage signal terminal VSS. The third capacitor C3 has a bootstrap effect to maintain the voltage of the third node N3.

It will be understood that for the first capacitor C1, the second capacitor C2 and the third capacitor C3, the capacitance may be all the same or all different, or the capacitance of any two may be the same and different from the capacitance of the other. The capacitance of the first capacitor C1, the second capacitor C2 and the third capacitor C3 may be set as required, as long as the same technical concept as the present disclosure is adopted.

In some embodiments, referring to FIGS. 9A and 9B, the shift register 310 further includes a reset sub-circuit 37 and an initialization sub-circuit 38. The reset sub-circuit 37 is electrically connected to the third clock signal terminal CK4, the first voltage signal terminal VSS and the first node N1. The reset sub-circuit 37 is configured to, under the control of the third clock signal from the third clock signal terminal CK4, transmit the first voltage signal transmitted from the first voltage signal terminal VSS to the first node N1 to reset the voltage of the first node N1, so as to prevent the voltage of the first node N1 from remaining to the next display period. The initialization sub-circuit 38 is electrically connected to the first clock signal terminal CK1, the first voltage signal terminal VSS and the third node N3. The initialization sub-circuit 38 is configured to, under the control of the first clock signal from the first clock signal terminal CK1, transmit the first voltage signal VSS to the third node N3 to initialize the voltage of the third node N3.

As shown in FIG. 9B, the reset sub-circuit 37 includes a twenty-second transistor T22. A control electrode of the twenty-second transistor T22 is electrically connected to the third clock signal terminal CK4, a first electrode of the twenty-second transistor T22 is electrically connected to the first voltage signal terminal VSS, and a second electrode of the twenty-second transistor T22 is electrically connected to the first node N1. In a case where the third clock signal terminal CK4 transmits a third clock signal, the twenty-second transistor T22 is turned on and transmits the first voltage signal transmitted by the first voltage signal terminal VSS to the first node N1, so that the voltage of the first node N1 is a low voltage, and the reset function for the voltage of the first node N1 is realized.

The initialization sub-circuit 38 includes a twenty-third transistor T23. A control electrode of the twenty-third transistor T23 is electrically connected to the first clock signal terminal CK1, a first electrode of the twenty-third transistor T23 is electrically connected to the first voltage signal terminal VSS, and a second electrode of the twenty-third transistor T23 is electrically connected to the third node N3. In a case where the first clock signal terminal CK1 transmits a first clock signal, the twenty-third transistor T23 is turned on and transmits the first voltage signal transmitted by the first voltage signal terminal VSS to the third node N3 to initialize the voltage of the third node N3.

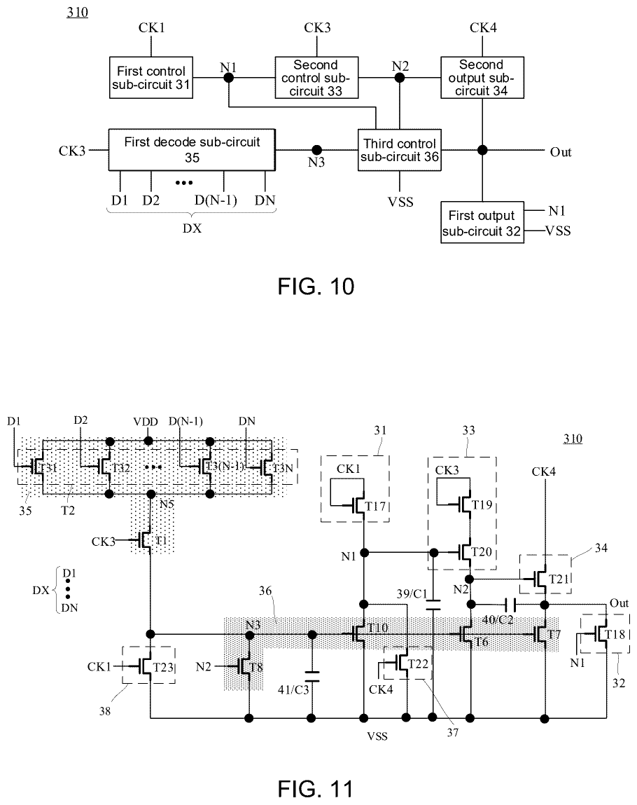

FIG. 10 is a diagram showing a circuit structure of the shift register in a case where the third control sub-circuit is further connected to the first node.

Referring to FIG. 10, in some embodiments, the third control sub-circuit 36 is further electrically connected to the first node N1, the third control sub-circuit 36 is further configured to, in a case where the shift register 310 is selected not to output a scanning signal, transmit the first voltage signal from the first voltage signal terminal VSS to the first node N1, so as to make the first node N1 at a non-operating voltage and control the second control sub-circuit 33 (the twentieth transistor T20) to be turned off.

FIG. 11 is an equivalent circuit diagram of the shift register shown in FIG. 10.

Referring to FIG. 11, in some embodiments, the third control sub-circuit 36 further includes a tenth transistor T10. A control electrode of the tenth transistor T10 is electrically connected to the third node N3, a first electrode of the tenth transistor T10 is electrically connected to the first voltage signal terminal VSS, and a second electrode of the tenth transistor T10 is electrically connected to the first node N1.

It will be understood that, in a case where the third control sub-circuit 36 includes the tenth transistor T10, the first decode sub-circuit 35 may have the structure shown in FIG. 7 or the structure shown in FIG. 8. FIG. 10 is illustrated only by taking an example in which the first decode sub-circuit 35 has the structure shown in FIG. 8. Based on the present disclosure, those skilled in the art may combine the above-mentioned embodiments to obtain different embodiments, and the embodiments obtained by combining different embodiments all belong to the protection scope of the present application.

With continued reference to FIG. 11, as described above, in the case where the shift register 310 is selected to output no scanning signal, the first decode sub-circuit 35 transmits a second voltage signal to the third node N3, and the tenth transistor T10 is turned on under the control of the second voltage signal. The tenth transistor T10 transmits the first voltage signal transmitted by the first voltage signal terminal VSS to the first node N1, so that the first node N1 is at a non-operating voltage. The voltage of the first node N1 controls the twentieth transistor T20 to be in an off state, and the second control sub-circuit 33 cannot transmit the second clock signal from the second clock signal terminal CK3 to the second node N2.

In the case where the shift register 310 is selected to output a scanning signal, the voltage of the third node N3 is a low voltage, the tenth transistor T10 is in an off state, which will not affect the voltage of the first node N1. The seventeenth transistor T17 may transmit the first clock signal to the first node N1 under the control of the first clock signal, so that the voltage of the first node N1 is kept high.

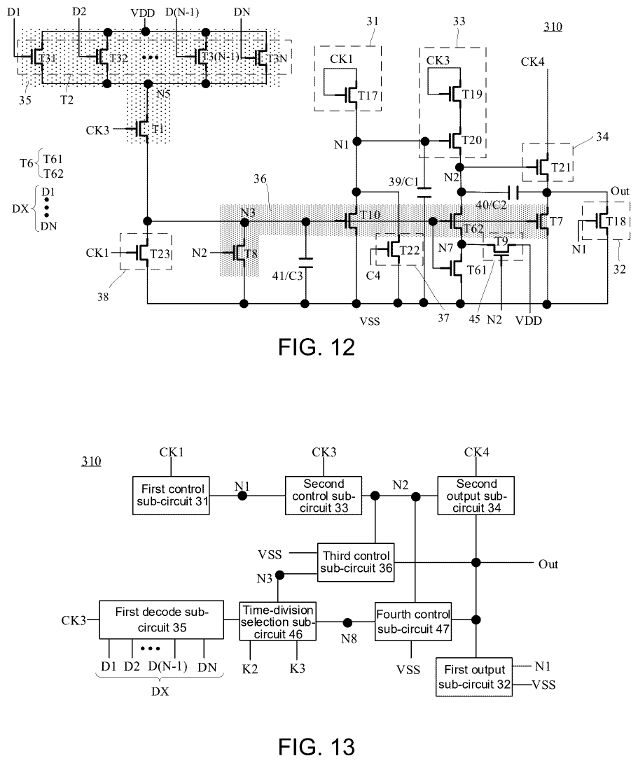

FIG. 12 is an equivalent circuit diagram of a shift register including an anti-leakage sub-circuit.

Referring to FIG. 12, in some embodiments, the sixth transistor T6 is a dual-gate transistor, the sixth transistor T6 includes two sub-transistors connected in series, and the two sub-transistors are connected via a seventh node N7, which is conducive to reducing the leakage current of the sixth transistor T6 to reduce the voltage drop of the second node N2.

For example, the two sub-transistors are respectively a first sub-transistor T61 and a second sub-transistor T62. A control electrode of the first sub-transistor T61 is electrically connected to the third node N3, a first electrode of the first sub-transistor T61 is electrically connected to the first voltage signal terminal VSS, and a second electrode of the first sub-transistor T61 is electrically connected to the seventh node N7. A control electrode second sub-transistor T62 is electrically connected to the third node N3, a first electrode of the second sub-transistor T62 is electrically connected to the seventh node N7, and a second electrode of the second sub-transistor T62 is electrically connected to the second node N2.

The shift register 310 further includes an anti-leakage sub-circuit 45, the anti-leakage sub-circuit 45 is electrically connected to the second node N2, the second voltage signal terminal VDD and the seventh node N7, and the anti-leakage sub-circuit 45 is configured to, under the control of the voltage of the second node N2, transmit the second voltage signal from the second voltage signal terminal VDD to the seventh node N7. For example, in a case where the second control sub-circuit 33 transmits a second clock signal to the second node N2, the voltage of the second node N2 is a high voltage, and the second node N2 controls the anti-leakage sub-circuit 45 to transmit the second voltage signal to the seventh node N7, which can reduce the voltage difference between the first electrode and the second electrode of the second sub-transistor T62 (the seventh node N7 and the second node N2), thereby reducing the leakage current of the second sub-transistor T62.

Referring to FIG. 12, in some embodiments, the anti-leakage sub-circuit 45 includes a ninth transistor T9, a control electrode of the ninth transistor T9 is electrically connected to the second node N2, a first electrode of the ninth transistor T9 is electrically connected to the second voltage signal terminal VDD, and a second electrode of the ninth transistor T9 is electrically connected to the seventh node N7. For example, in the case where the voltage of the second node N2 is a high voltage, the ninth transistor T9 is turned on and transmits the second voltage signal to the seventh node N7.

FIG. 13 is a structural diagram of a shift register including a time-division selection sub-circuit and a fourth control sub-circuit.

Referring to FIG. 13, in some embodiments, the shift register 310 further includes a time-division selection sub-circuit 46 and a fourth control sub-circuit 47. The time-division selection sub-circuit 46 is electrically connected to a second control signal terminal K2, a third control signal terminal K3, the first decode sub-circuit 35, the third node N3 and an eighth node N8. The time-division selection sub-circuit 46 is configured to electrically connect the first decode sub-circuit 35 to the third node N3 under the control of a second control signal from the second control signal terminal K2, and electrically connect the first decode sub-circuit 35 to the eighth node N8 under the control of a third control signal from the third control signal terminal K3. The first decode sub-circuit 35 is electrically connected to the third node N3 via the time-division selection sub-circuit 46.

For example, in a display period, one of the second control signal terminal and the third control signal terminal transmits a corresponding control signal. For example, in a display period, the second control signal terminal K2 transmits a second control signal, or the third control signal terminal K3 transmits a third control signal.

For example, in different display periods, the second control signal terminal K2 and the third control signal terminal K3 alternately output corresponding control signals. For example, in two consecutive display periods, the second control signal terminal K2 transmits a second control signal in one display period, and the third control signal terminal K3 transmits a third control signal in the other display period. In this way, the signal (e.g., second voltage signal or second clock signal) output by the first decode sub-circuit 35 may be alternately transmitted to the third node N3 and the eighth node N8.

The fourth control sub-circuit 47 is electrically connected to the first voltage signal terminal VSS, the second node N2, the eighth node N8 and the signal output terminal Out. The fourth control sub-circuit 47 is configured to transmit the first voltage signal from the first voltage signal terminal VSS to the second node N2 and the signal output terminal Out in the case where the shift register 310 is selected not to output a scanning signal, and transmit the first voltage signal from the first voltage signal terminal VSS to the eighth node N8 in the case where the shift register 310 is selected to output a scanning signal. The fourth control sub-circuit 47 can realize the same function as the third control sub-circuit 46. Based on this, in different display periods, the third control sub-circuit 36 and the fourth control sub-circuit 47 alternately control the voltages of the second node N2 and the signal output terminal Out, which may prevent the transistors (e.g., the sixth transistor T6, the seventh transistor T7 and the tenth transistor T10) controlled by the third node N3 from being in a same bias state for a long time, so as to reduce the risk that the transistors controlled by the third node N3 are unable to be turned on or off normally caused by the threshold voltage shift.

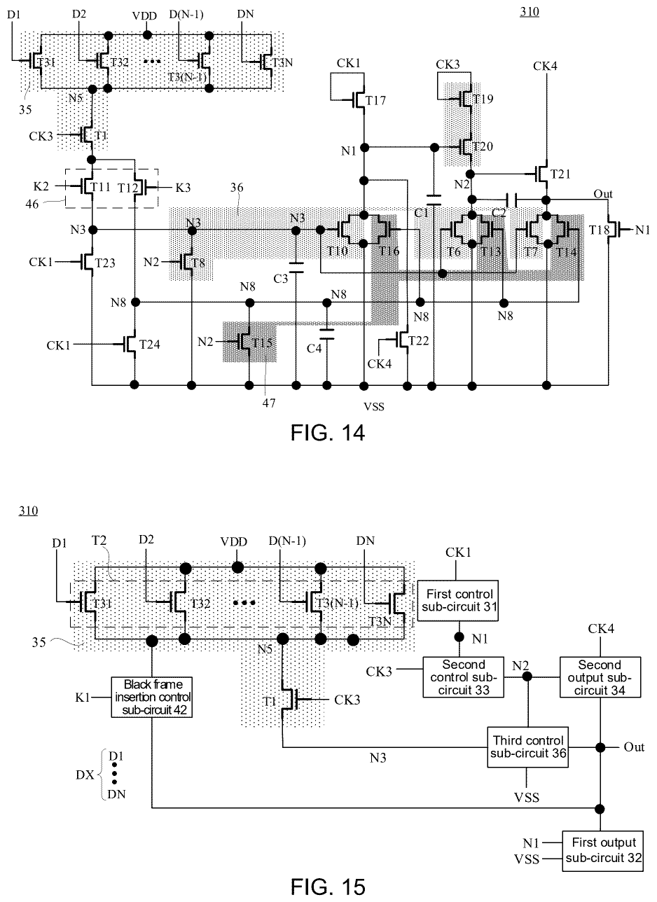

FIG. 14 is an equivalent circuit diagram of a shift register including a time-division selection sub-circuit and a fourth control sub-circuit.

Referring to FIG. 14, in some embodiments, the time-division selection sub-circuit 46 includes an eleventh transistor T11 and a twelfth transistor T12. A control electrode of the eleventh transistor T11 is electrically connected to the second control signal terminal K2, a first electrode of the eleventh transistor T11 is electrically connected to the first decode sub-circuit 35 (e.g., the second electrode of the first transistor T1), and a second electrode of the eleventh transistor T11 is electrically connected to the third node N3. A control electrode of the twelfth transistor T12 is electrically connected to the third control signal terminal K3, a first electrode of the twelfth transistor T12 is electrically connected to the first decode sub-circuit 35 (e.g., the second electrode of the first transistor), and a second electrode of the twelfth transistor T12 is electrically connected to the eighth node N8.

For example, in the case where the first decode sub-circuit 35 selects the shift register 310 to output no scanning signal, the first decode sub-circuit 35 transmits the second voltage signal to the time-division selection sub-circuit 46. In a first display period, the second control signal terminal K2 transmits a second control signal, the eleventh transistor T11 is turned on, and the eleventh transistor T11 transmits the second voltage signal to the third node N3. Meanwhile, the third control signal terminal K3 does not transmit a third control signal, the twelfth transistor T12 is turned off, and the second voltage signal is not transmitted to the eighth node N8. The third control sub-circuit 36 transmits the first voltage signal to the second node N2 and the signal output terminal Out. In a second display period, the third control signal terminal K3 transmits a third control signal, the twelfth transistor T12 is turned on, and the twelfth transistor T12 transmits the second voltage signal to the eighth node N8. Meanwhile, the second control signal terminal K2 does not transmit the second control signal, the eleventh transistor T11 is turned off, and the second voltage signal is not transmitted to the third node N3. In this case, the fourth control sub-circuit 47 transmits the first voltage signal to the second node N2 and the signal output terminal Out.

With continued reference to FIG. 14, in some embodiments, the fourth control sub-circuit 47 includes a thirteenth transistor T13, a fourteenth transistor T14, a fifteenth transistor T15 and a sixteenth transistor T16. A control electrode of the thirteenth transistor T13 is electrically connected to the eighth node N8, a first electrode of the thirteenth transistor T13 is electrically connected to the first voltage signal terminal VSS, and a second electrode of the thirteenth transistor T13 is electrically connected to the second node N2. A control electrode of the fourteenth transistor T14 is electrically connected to the eighth node N8, a first electrode of the fourteenth transistor T14 is electrically connected to the first voltage signal terminal VSS, and a second electrode of the fourteenth transistor T14 is electrically connected to the signal output terminal Out. A control electrode of the fifteenth transistor T15 is electrically connected to the second node N2, a first electrode of the fifteenth transistor T15 is electrically connected to the first voltage signal terminal VSS, and a second electrode of the fifteenth transistor T15 is electrically connected to the eighth node N8. A control electrode of the sixteenth transistor T16 is electrically connected to the eighth node N8, a first electrode of the sixteenth transistor T16 is electrically connected to the first voltage signal terminal VSS, and a second electrode of the sixteenth transistor T16 is electrically connected to the first node N1.

In the case where the shift register 310 is selected to output no scanning signal and the time-division selection sub-circuit 46 transmits the second voltage signal from the second voltage signal terminal VDD to the eighth node N8, the voltage of the eighth node N8 (the second voltage signal) controls the thirteenth transistor T13, the fourteenth transistor T14 and the sixteenth transistor T16 to be turned on. The thirteenth transistor T13 transmits the first voltage signal from the first voltage signal terminal VSS to the second node N2, the voltage of the second node N2 is a low voltage. The fourteenth transistor T14 transmits the first voltage signal from the first voltage signal terminal VSS to the signal output terminal Out, and the signal output terminal Out outputs a low voltage, i.e., outputs no scanning signal. The sixteenth transistor T16 transmits the first voltage signal from the first voltage signal terminal VSS to the first node N1, and the first node N1 maintains at a low voltage. The voltage of the second node N2 is a low voltage, and the fifteenth transistor T15 is turned off under the control of the second node N2, which will not affect the voltage of the eighth node N8.

In some embodiments, as shown in FIG. 14, the shift transistor 310 may further include a twenty-fourth transistor T24 and a fourth capacitor C4. A control electrode of the twenty-fourth transistor T24 is electrically connected to the first clock signal terminal CK1, a first electrode of the twenty-fourth transistor T24 is electrically connected to the first voltage signal terminal VSS, and a second electrode of the twenty-fourth transistor T24 is electrically connected to the eighth node N8. In a case where the first clock signal terminal CK1 transmits a first clock signal, the twenty-fourth transistor T24 is turned on and transmits the first voltage signal transmitted by the first voltage signal terminal VSS to the eight node N8, so as to initialize the voltage of the eighth node N8. One plate of the fourth capacitor C4 is electrically connected to the first voltage signal terminal VSS, the other plate of the fourth capacitor C4 is electrically connected to the eighth node N8, and the fourth capacitor C4 is configured to maintain the voltage of the eighth node N8.

FIG. 4B is another driving timing diagram of the pixel circuit 100 shown in FIG. 3.

During the display process of the display panel, in order to alleviate the problem of image smearing (afterimage) when switching dynamic images, a black frame is generally inserted in the display interval of a frame to enhance the motion picture response time (MPRT) of the display image. Referring to FIGS. 3 and 4B, in some embodiments, a display period of the pixel circuit 100 may further include a black frame insertion data writing phase M103 and a black frame insertion holding phase M104 between the light-emitting phase M102 and the sensing phase M105.

In the black frame insertion data writing phase M103, the first scanning signal terminal G1 and the second scanning signal terminal G2 output a high voltage, the data writing transistor T101 and the sensing transistor T103 are turned on, and the data writing transistor T101 transmits a black frame insertion data signal transmitted by the data line DL to the first circuit node S1.

In the black frame insertion holding phase M104, the first scanning signal terminal G1 and the second scanning signal terminal G2 output a low voltage, and the data writing transistor T101 and the sensing transistor T103 are both turned off. The driving transistor T102 is turned off under the control of the black frame insertion data signal, and the light-emitting device stops emitting light.

FIG. 15 is a circuit structure diagram of a shift register including a black frame insertion control sub-circuit.

Referring to FIG. 15, in some embodiments, in the case where the first decode sub-circuit 35 has the structure shown in FIG. 8, the shift register 310 further includes a black frame insertion control sub-circuit 42. The black frame insertion control sub-circuit 42 is electrically connected to a first control signal terminal K1, the fifth node N5 and the signal output terminal Out, and is configured to transmit the voltage of the fifth node N5 to the signal output terminal Out under the control of a first control signal from the first control signal terminal K1.

In a case where the black frame insertion data writing is required, the rows requiring black frame insertion may be selected through the plurality of groups of selection control signal lines KL, and at least one second transistor T2 in the plurality of second transistors T2 is selected to be turned on to transmit the second voltage signal transmitted by the second voltage signal terminal VDD to the fifth node N5. The first control signal terminal K1 transmits a first control signal to transmit the second voltage signal received by the fifth node N5 to the signal output terminal Out, so that the shift register 310 outputs a scanning signal.

It will be understood that, in the case where black frame insertion data writing is required, the first clock signal terminal CK1, the second clock signal terminal CK3 and the third clock signal terminal CK4 all do not transmit corresponding clock signals to prevent the first decode sub-circuit 35 from affecting the voltage of the third node N3.

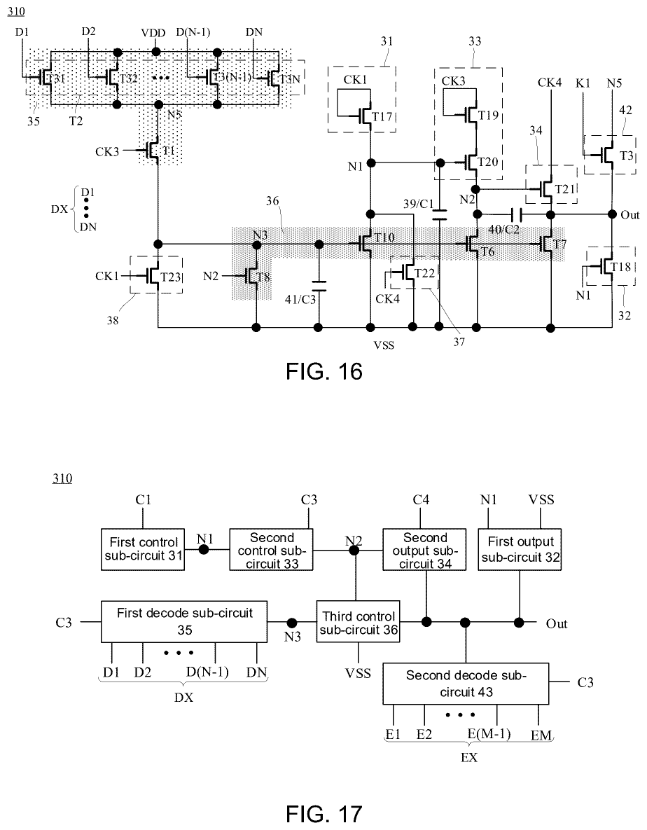

FIG. 16 is an equivalent circuit diagram of a shift register including a black frame insertion control sub-circuit.

Referring to FIG. 16, in some embodiments, the black frame insertion control sub-circuit 42 includes a third transistor T3, a control electrode of the third transistor T3 is electrically connected to the first control signal terminal K1, a first electrode of the third transistor T3 is electrically connected to the fifth node N5, and a second electrode of the third transistor T3 is electrically connected to the signal output terminal Out.

In the case where black frame insertion data writing is required, at least one second transistor T2 (e.g., the first selection transistor T31) in the plurality of second transistors T2 is turned on, and the at least one second transistor T2 that is turned on transmits the second voltage signal to the fifth node N5. The third transistor T3 is turned on under the control of the first control signal from the first control signal terminal K1, and transmits the second voltage signal received by the fifth node N5 to the signal output terminal Out, so that the shift register 310 outputs a scanning signal.

FIG. 17 is a circuit structure diagram of a shift register including a second decode sub-circuit.

In some other embodiments, referring to FIG. 17, the shift register 310 may further include a second decode sub-circuit 43, and the second decode sub-circuit 43 is configured to control the shift register 310 to output a scanning signal in a case where black frame insertion data writing is required.

The second decode sub-circuit 43 is electrically connected to a plurality of black frame insertion control signal terminals EX, the first control signal terminal K1, the second voltage signal terminal VDD and the signal output terminal Out. For example, as shown in FIG. 17, the second decode sub-circuit 43 is electrically connected to M black frame insertion control signal terminals EX, where M is a positive integer greater than 0, and the M black frame insertion control signal terminals EX are sequentially denoted as a first black frame insertion control signal terminal E1, a second black frame insertion control signal terminal E2, . . . , an (M-1)-th black frame insertion control signal terminal E(M-1) and an M-th black frame insertion control signal terminal EM.

The second decode sub-circuit 43 is configured to, under the control of a black frame insertion control signal from at least one black frame insertion control signal terminal EX and the first control signal from the first control signal terminal K1, transmit the second voltage signal from the second voltage signal terminal VDD to the signal output terminal Out. In a case where the at least one black frame insertion control signal terminal EX transmits a black frame insertion control signal and the first control signal terminal K1 transmits the first control signal, the second decode sub-circuit 43 transmits the second voltage signal to the signal output terminal Out, so that the shift register 310 outputs a scanning signal to drive the pixel circuit to implement the function of black frame insertion data writing.

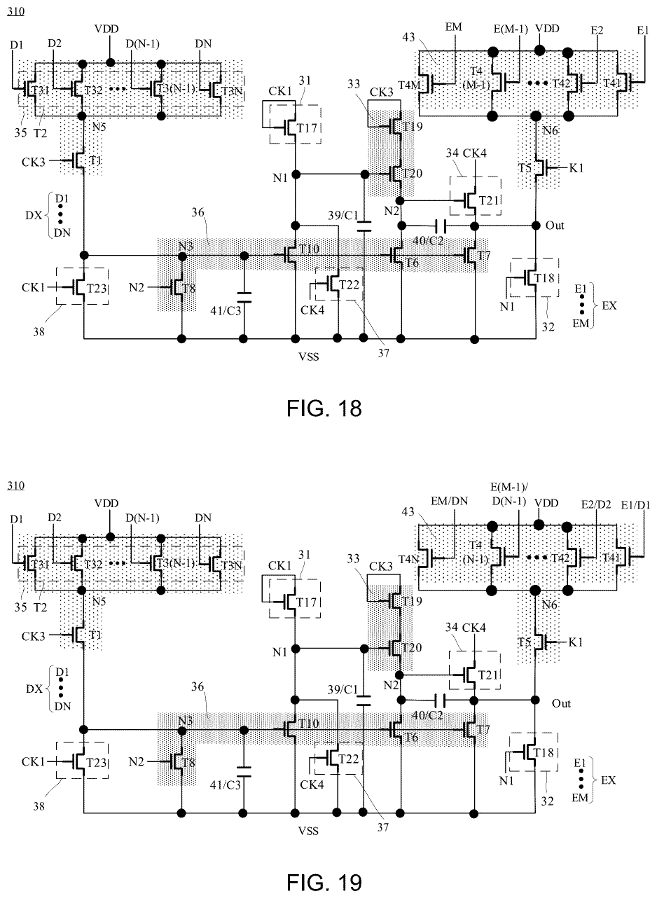

FIG. 18 is an equivalent circuit diagram of a shift register including a second decode sub-circuit. FIG. 18 is illustrated by taking an example in which the first decode sub-circuit 35 has the structure shown in FIG. 8. It will be understood that, the first decode sub-circuit 35 may have the structure shown in FIG. 7.

Referring to FIG. 18, in some embodiments, the second decode sub-circuit includes a plurality of fourth transistors T4 and a fifth transistor T5. A control electrode of each fourth transistor T4 in the plurality of fourth transistors T4 is electrically connected to a black frame insertion control signal terminal EX, first electrodes of the plurality of fourth transistors T4 are all electrically connected to the second voltage signal terminal VDD, and second electrodes of the plurality of fourth transistors T4 are all electrically connected to a sixth node N6. A control electrode of the fifth transistor T5 is electrically connected to the first control signal terminal K1, a first electrode of the fifth transistor T5 is electrically connected to the sixth node N6, and a second electrode of the fifth transistor T5 is electrically connected to the signal output terminal Out.

For example, the second decode sub-circuit includes M fourth transistors T4, and the M fourth transistors T4 are sequentially denoted as a first black frame insertion control transistor T41, a second black frame insertion control transistor T42, . . . , an (M-1)-th black frame insertion control transistor T4(M-1) and an M-th black frame insertion control transistor T4M. A control electrode of the first black frame insertion control transistor T41 is electrically connected to the first black frame insertion control signal terminal E1, a control electrode of the second black frame insertion control transistor T42 is electrically connected to the second black frame insertion control signal terminal E2, . . . , a control electrode of the (M-1)-th black frame insertion control transistor T4(M-1) is electrically connected to the (M-1)-th black frame insertion control signal terminal E(M-1), and a control electrode of the M-th black frame insertion control transistor T4M is electrically connected to the M-th black frame insertion control signal terminal EM.

In a case where at least one black frame insertion control signal terminal EX of the M black frame insertion control signal terminals EX transmits a black frame insertion control signal, a fourth transistor T4 that is electrically connected to the black frame insertion control signal terminal EX transmitting the black frame insertion control signal is turned on, and the fourth transistor T4 that is turned on transmits the second voltage signal to the sixth node N6. For example, the first black frame insertion control signal terminal E1 transmits a black frame insertion control signal, the first black frame insertion control transistor T41 that is electrically connected to the first black frame insertion control signal terminal E1 is turned on, and the first black frame insertion control transistor T41 transmits the second voltage signal to the sixth node N6.

FIG. 19 is an equivalent circuit diagram in which a plurality of black frame insertion control signal terminals are in one-to-one correspondence with the plurality of selection control signal terminals.

Referring to FIG. 19, in some embodiments, the number of the plurality of black frame insertion control signal terminals EX is the same as the number of the plurality of selection control signal terminals DX, and the plurality of black frame insertion control signal terminals EX are in one-to-one correspondence with the plurality of selection control signal terminals DX. That is, the number of the black frame insertion control signal terminals EX is equal to the number of the selection control signal terminals DX, so that the number of the second transistors T2 is equal to the number of the fourth transistors T4; this is, M=N.

A black frame insertion control signal terminal EX and a selection control signal terminal DX corresponding to the black frame insertion control signal terminal EX are a same signal terminal. For example, the first black frame insertion control signal terminal E1 and the first selection control signal terminal D1 are a same signal terminal, the second black frame insertion control signal terminal E2 and the second selection control signal terminal D2 are a same signal terminal, . . . , the M-th black frame insertion control signal terminal EM and the N-th selection control signal terminal DN are a same signal terminal. In this way, it is conducive to simplifying the structure of the shift register 310 and simplifying the structure of the gate driving circuit.

Alternatively, at least one black frame insertion control signal terminal EX and selection control signal terminal(s) DX corresponding to the black frame insertion control signal terminal(s) EX are different signal terminals. For example, the first black frame insertion control signal terminal E1 and the first selection control signal terminal D1 are different signal terminals. Thus, in a case where the first selection control signal terminal D1 is electrically connected to the first group first selection control signal line KL1′, the first black frame insertion control signal terminal E1 may be electrically connected to the first group second selection control signal line KL1. That is, the first decode sub-circuit 35 and the second decode sub-circuit 43 share the plurality of groups of selection control signal lines KL. Based on this, the number of signal lines for controlling the gate driving circuit may be reduced, which is conducive to reducing the width of the peripheral area BB and achieving narrow bezel of the display device.

It will be understood that, in some other embodiments, the number of black frame insertion control signal terminals EX and the number of selection control signal terminals DX may be different; that is, the number of second transistors T2 and the number of fourth transistors T4 may be different. For example, the number of black frame insertion control signal terminals EX is less than the number of selection control signal terminals DX; this is, M<N; in this case, the second decode sub-circuit 43 may still share the plurality of groups of selection control signal lines KL with the first decode sub-circuit 35. Alternatively, the number of black frame insertion control signal terminals EX is greater than the number of selection control signal terminals DX; that is, M>N; in this case, the N fourth transistors T4 of the second decode sub-circuit 43 may share the plurality of groups of selection control signal lines KL with the first decode sub-circuit 35, and the other fourth transistors T4 are controlled by other signal lines provided additionally. Alternatively, no matter whether the number of the black frame insertion control signal terminals EX is the same as the number of the selection control signal terminals DX, the first decode sub-circuit 35 and the second decode sub-circuit 43 may be controlled by using different signal lines.

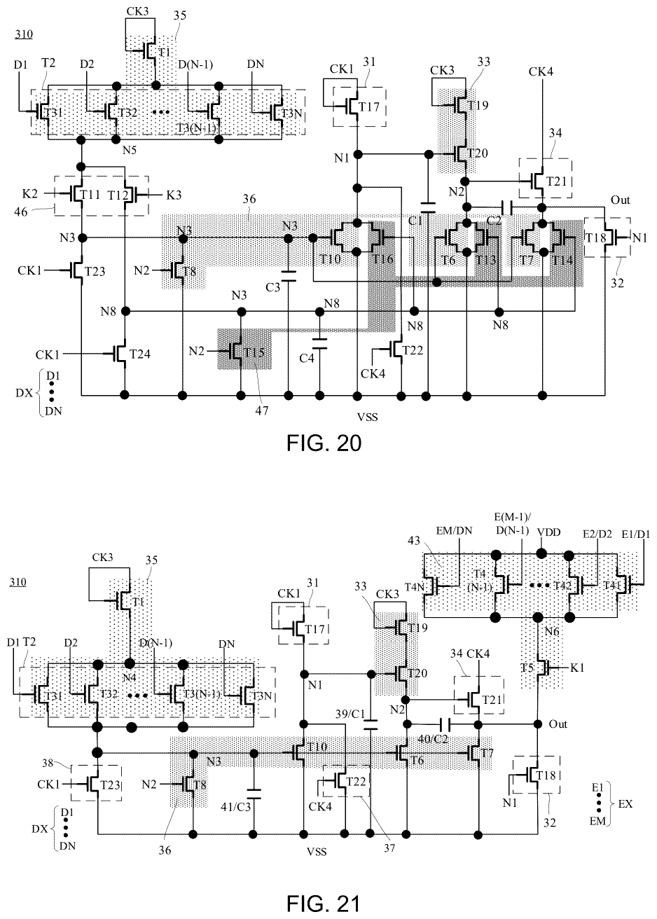

FIG. 20 to FIG. 22 are equivalent circuit diagrams of a shift register 310 obtained by combining the above embodiments.

It will be understood that, the above embodiments may be implemented separately, or multiple embodiments may be selected and implemented in combination.

For example, referring to FIG. 20, a first electrode and a control electrode of the first transistor T1 of the first decode sub-circuit 35 are both electrically connected to the second clock signal terminal CK3, a second electrode of the first transistor T1 is electrically connected to first electrodes of the second transistors T2, and second electrodes of the second transistors T2 are electrically connected to the third node N3 and the eighth node N8 through the time-division control sub-circuit 46.

For example, referring to FIG. 21, a first electrode and a control electrode of the first transistor T1 of the first decode sub-circuit 35 are both electrically connected to the second clock signal terminal CK3, a second electrode of the first transistor T1 is electrically connected to first electrodes of the second transistors T2, and second electrodes of the second transistors T2 are electrically connected to the third node N3. The shift register 310 further includes a second decode sub-circuit 43. For the structure and connection relationship of the second decode sub-circuit 43, reference may be made to the above-described content and will not be repeated here.

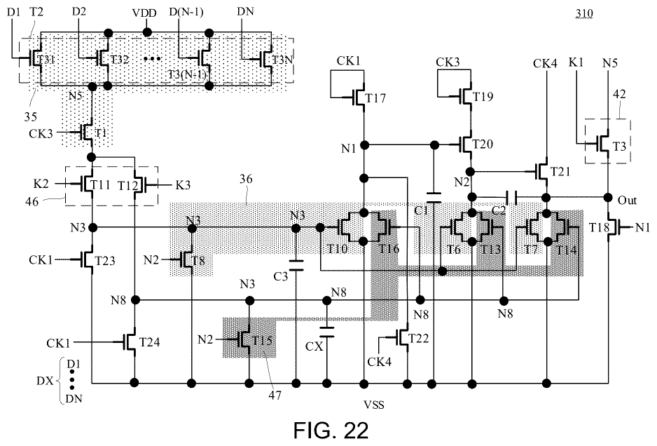

For example, referring to FIG. 22, the first decode sub-circuit 35 is further electrically connected to the second voltage signal terminal VDD, first electrodes of the second transistors T2 are electrically connected to the second voltage signal terminal VDD, and second electrodes of the second transistors T2 are electrically connected to a first electrode of the first transistor T1. The shift register 310 further includes a black frame insertion control sub-circuit 42, a time-division control sub-circuit 46 and a fourth control sub-circuit 47. For the structures and connection relationships of the black frame insertion control sub-circuit 42, the time-division control sub-circuit 46 and the fourth control sub-circuit 47, reference may be made to the above-described content and will not be repeated here.

It will be understood that, there may exist other combinations of embodiments for the shift register 310, as long as the same technical concept is adopted. The above embodiments merely include part of the embodiments rather than all the embodiments. For example, it is also possible to configure the sixth transistor T6 as a dual-gate transistor and provide an anti-leakage sub-circuit based on any of the embodiments shown in FIGS. 20 to 22, and other combinations will not be listed one by one in the present disclosure.

Referring to FIG. 5, in some embodiments, in the plurality of shift registers 310 included in the gate driving circuit 300, every four shift registers 310 constitute a shift register group 310′, and the four shift registers 310 included in the shift register group 310′ are sequentially arranged as a first-stage shift register 311, a second-stage shift register 312, a third-stage shift register 313, and a fourth-stage shift register 314.

The gate driving circuit 300 further includes a first clock signal line CL1, a second clock signal line CL2, a third clock signal line CL3, and a fourth clock signal line CL4. The first clock signal line CL1 is electrically connected to a first clock signal terminal CK1 of the first-stage shift register 311, a third clock signal terminal CK4 of the second-stage shift register 312, and a second clock signal terminal CK3 of the third-stage shift register 313. The second clock signal line CL2 is electrically connected to a first clock signal terminal CK1 of the second-stage shift register 312, a third clock signal terminal CK4 of the third-stage shift register 313, and a second clock signal terminal CK3 of the fourth-stage shift register 314. The third clock signal line CL3 is electrically connected to a second clock signal terminal CK3 of the first-stage shift register 311, a first clock signal terminal CK1 of the third-stage shift register 313, and a third clock signal terminal CK4 of the fourth-stage shift register 314. The fourth clock signal line CL4 is electrically connected to a third clock signal terminal CK4 of the first-stage shift register 311, a second clock signal terminal CK3 of the second-stage shift register 312, and a first clock signal terminal CK1 of the fourth-stage shift register 314.

The first clock signal terminal CK1 of the first-stage shift register 311 is electrically connected to the first clock signal line CL1, the first clock signal terminal CK1 of the second-stage shift register 312 is electrically connected to the second clock signal line CL2, the first clock signal terminal CK1 of the third-stage shift register 313 is electrically connected to the third clock signal line CL3, and the first clock signal terminal CK1 of the fourth-stage shift register 314 is electrically connected to the fourth clock signal line CL4.

The second clock signal terminal CK3 of the first-stage shift register 311 is electrically connected to the third clock signal line CL3, the second clock signal terminal CK3 of the second-stage shift register 312 is electrically connected to the fourth clock signal line CL4, the second clock signal terminal CK3 of the third-stage shift register 313 is electrically connected to the first clock signal line CL1, and the second clock signal terminal CK3 of the fourth-stage shift register 314 is electrically connected to the second clock signal line CL2.

The third clock signal terminal CK4 of the first-stage shift register 311 is electrically connected to the fourth clock signal line CL4, the third clock signal terminal CK4 of the second-stage shift register 312 is electrically connected to the first clock signal line CL1, the third clock signal terminal CK4 of the third-stage shift register 313 is electrically connected to the second clock signal line CL2, and the third clock signal terminal CK4 of the fourth-stage shift register 314 is electrically connected to the third clock signal line CL3.

Based on this, the first decode sub-circuit 35 and the first clock signal line CL1, the second clock signal line CL2, the third clock signal line CL3 and the fourth clock signal line CL4 may allow the shift registers 310 to compile (4×2^{N}) different compiling states in total. For example, in a case where N is 10, a total of (4×2¹⁰)=4096 compiling states may be compiled, which may be applied at least to a display device with a resolution of 4K×2K. It will be noted that the display device includes 2160 rows of sub-pixels at a resolution of 4K×2K.

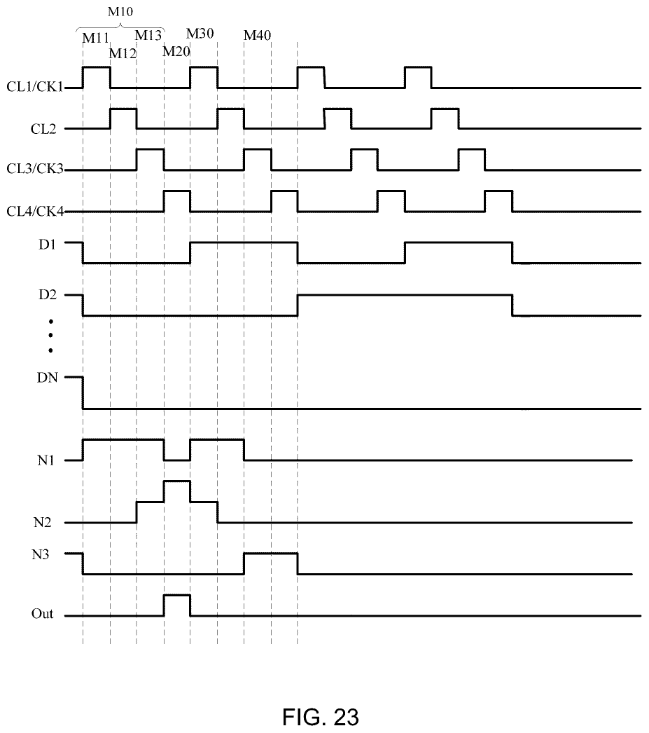

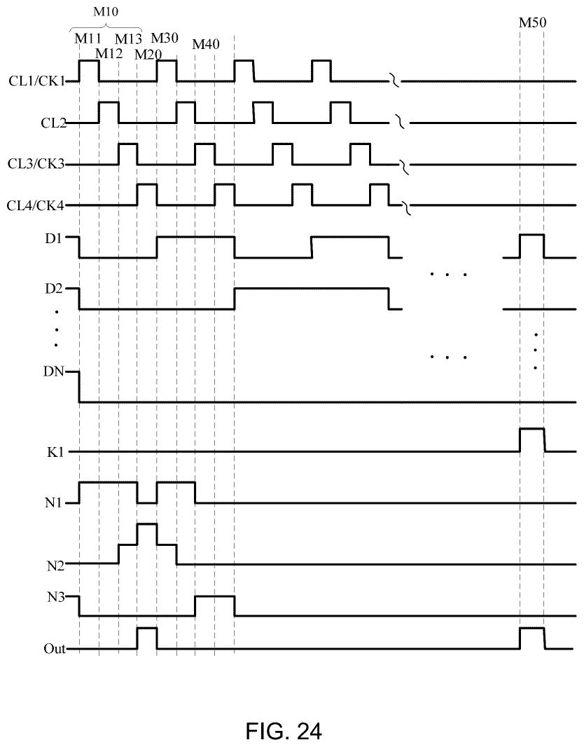

In some embodiments, the first clock signal line CL1, the second clock signal line CL2, the third clock signal line CL3, and the fourth clock signal line CL4 transmit an operating voltage in sequence (as shown in FIGS. 23 and 24), and one of the two selection control signal lines KL in each group of selection control signal lines KL transmits an operating voltage, and the other transmits a non-operating voltage.

In a case where the shift register 310 includes a second decode sub-circuit 43, the second decode sub-circuit 43 is electrically connected to one selection control signal line KL in each group of selection control signal lines KL, and a selection control signal line forms a black frame insertion control signal terminal EX. The first decode sub-circuit 35 and the second decode sub-circuit 43 share the plurality of groups of selection control signal lines KL. Based on this, the number of signal lines for controlling the gate driving circuit may be reduced, which is conducive to reducing the width of the peripheral area BB and realizing the narrow bezel of the display device.

Embodiments of the present disclosure provide a driving method of a shift register 310. Referring to FIGS. 23 and 24, a display period (a frame period) includes a selection phase M10 and an output phase M20.

In a case where the shift register 310 is selected to output no scanning signal, the driving method includes the following steps.

In the selection phase M10, at least one selection control signal terminal of the plurality of selection control signal terminals DX (D1 to DN) outputs an operating voltage (a high voltage), the first decode sub-circuit 35 transmits the operating voltage (a second voltage signal) to the third node N3, and the third control sub-circuit 36 transmits a first voltage signal to the second node N2 and the third node N3 under the control of the operating voltage of the third node N3.

In the output phase M20, the second output sub-circuit 34 does not output the scanning signal under the control of the first voltage signal of the second node N2.

FIG. 23 is a control timing diagram of a shift register, in accordance with some embodiments. In FIG. 23, the shift register is driven based on the circuit structure of the shift register 310 shown in FIG. 11, and in the shift register shown in FIG. 11, the first clock signal terminal CK1 is electrically connected to the first clock signal line CL1, the second clock signal terminal CK3 is electrically connected to the third clock signal line CL3, and the third clock signal terminal CK4 is electrically connected to the fourth clock signal line CL4.

In a case where the shift register is selected to output a scanning signal, referring to FIG. 23, the driving method includes the following steps.

In the selection phase M10, the plurality of selection control signal terminals DX (D1 to DN) all transmit a non-operating voltage, and the second control sub-circuit 33 transmit a second clock signal from the second clock signal terminal CK3 to the second node N2.

In the output phase M20, the second output sub-circuit 34 transmits a third clock signal from the third clock signal terminal CK4 to the signal output terminal Out under the control of the voltage of the second node N2 to output the third clock signal.

With continued reference to FIG. 23, in some embodiments, the selection phase M10 includes a first phase M11 and a third phase M13 that are sequentially arranged.

In the first phase M11, the first control sub-circuit 31, under the control of a first clock signal from the first clock signal terminal CK1 (the first clock signal line CL1), transmits the first clock signal to the first node N1.

For example, as shown in FIG. 11, in the first phase M11, the first clock signal terminal CK1 transmits a first clock signal (a high voltage), the seventeenth transistor T17 is turned on, and the seventeenth transistor T17 transmits the first clock signal from the first clock signal terminal CK1 to the first node N1; in this case, the voltage of the first node N1 is a high voltage.

The eighteenth transistor T18 is turned on under the control of the voltage of the first node N1, the eighteenth transistor T18 transmits a first voltage signal from the first voltage signal terminal VSS to the signal output terminal Out, so that the signal output terminal Out does not output a scanning signal.

The twenty-third transistor T23 is turned on, the twenty-third transistor T23 transmits the first voltage signal from the first voltage signal terminal VSS to the third node N3, and the voltage of the third node N3 is a low voltage. The sixth transistor T6, the seventh transistor T7, and the tenth transistor T10 are turned off under the control of the low voltage of the third node N3.

In some embodiments, as shown in FIG. 23, the selection phase M10 further includes a second phase M12 between the first phase M11 and the third phase M13.

In the second phase M12, the second clock signal line CL2 transmits a second clock signal. Since the shift register 310 is not connected to the second clock signal line CL2, the voltage of each node of the shift register 310 is not affected. The voltage of first clock signal terminal CK1 becomes low, the seventeenth transistor T17 is turned off, and the voltage of the first node N1 remains unchanged due to the action of the first capacitor C1.

With continued reference to FIG. 23, in the third phase M13, the second control sub-circuit 33 transmits the second clock signal to the second node N2 under the control of the second clock signal from the second clock signal terminal CK3 and the first clock signal of the first node N1.

For example, as shown in FIG. 11, in the third phase M13, the second clock signal terminal CK3 transmits a second clock signal (a high voltage), the nineteenth transistor T19 is turned on, and the nineteenth transistor T19 transmits the second clock signal from the second clock signal terminal CK3 to the second electrode of the nineteenth transistor T19.

The seventeenth transistor T17 is turned off, and the first node N1 is kept at a high voltage due to the action of the first capacitor C1. The twentieth transistor T20 is turned on under the control of the first node N1, the twentieth transistor T20 transmits the second clock signal that is transmitted to the second electrode of the nineteenth transistor T19 to the second node N2, so that the voltage of the second node N2 is a high voltage.

The first transistor T1 is turned on, and the plurality of second transistors T2 are all in an off state, so that the third node N3 outputs no signal and maintains at a low voltage.

The eighth transistor T8 is turned on under the control of the high voltage of the second node N2 and transmits a first voltage signal of the first voltage signal terminal VSS to the third node N3, so that the third node N3 continues to maintain at a low voltage.

In the output phase M20, the nineteenth transistor T19 is turned off, the second node N2 maintains at a high voltage due to the action of the second capacitor C2, and the twenty-first transistor T21 is turned on. The third clock signal terminal CK4 transmits a third clock signal, and the twenty-first transistor T21 transmits the third clock signal from the third clock signal terminal CK4 to the signal output terminal Out. The signal output terminal Out outputs a high-voltage scanning signal. Since the voltage of the signal output terminal Out is increased, the voltage of the second node N2 is raised due to the bootstrap effect of the second capacitor C2.

The third clock signal terminal CK4 transmits the third clock signal, the twenty-second transistor T22 is turned on, the twenty-second transistor T22 transmits the first voltage signal to the first node N1, the voltage of the first node N1 is a low voltage, the twentieth transistor T20 is turned off, and the voltage of the first node N1 is reset.

With continued reference to FIG. 23, after the output phase M20, the display period further includes a reset phase M30 and an initialization phase M40.

In the reset phase M30, the first clock signal terminal CK1 (the first clock signal line CL1) transmits a first clock signal, the seventeenth transistor T17 is turned on, and the seventeenth transistor T17 transmits the first clock signal to the first node N1, so that the voltage of the first node N1 is a high voltage.

The eighteenth transistor T18 is turned on under the control of the high voltage of the first node N1, and the eighteenth transistor T18 transmits a first voltage signal from the first voltage signal terminal VSS to the signal output terminal Out, so that the signal output terminal Out stops outputting a high-voltage scanning signal.

In the initialization phase M40, at least one selection control signal terminal DX transmits an operating voltage, and the second transistor(s) T2 transmits a second voltage signal from the second voltage signal terminal VDD to the fifth node N5. The second clock signal terminal CK3 transmits a second clock signal, the first transistor T1 is turned on, and the first transistor T1 transmits the second voltage signal received by the fifth node N5 to the third node N3, so that the voltage of the third node N3 is a high voltage.

The sixth transistor T6 is turned on under the control of the high voltage of the third node N3, and the sixth transistor T6 transmits the first voltage signal to the second node N2 to initialize the voltage of the second node N2. The seventh transistor T7 is turned on under the control of the high voltage of the third node N3, and the seventh transistor T7 transmits the first voltage signal to the signal output terminal Out, and the signal output terminal Out does not output a scanning signal. The tenth transistor T10 is turned on under the control of the high voltage of the third node N3, and the tenth transistor T10 transmits the first voltage signal to the first node N1 to initialize the voltage of the first node N1.

In some embodiments, referring to FIGS. 19 and 24, in a case where the shift register 310 includes a second decode sub-circuit 43, a display period further includes a black frame insertion phase M50 after the output phase M20. It will be understood that the black frame insertion phase M50 is also located after the initialization phase M40.

FIG. 24 is a control timing diagram of a shift register, in accordance with some embodiments. In FIG. 24, the shift register is driven based on the circuit structure of the shift register 310 shown in FIG. 19.

Referring to FIG. 24, the driving method further includes the following steps.

In the black frame insertion phase M50, referring to FIG. 24, the second decode sub-circuit 43 transmits a second voltage signal from the second voltage signal terminal VDD to the signal output terminal Out under the control of a black frame insertion control signal (a selection control signal) from at least one black frame insertion control signal terminal EX (selection control signal terminal(s) DX) and a first control signal from the first control signal terminal K1, so that the signal output terminal Out outputs a scanning signal.

For example, referring to FIGS. 19 and 23, the first black frame insertion control signal terminal E1 transmits a black frame insertion control signal, the first black frame insertion control transistor T41 that is electrically connected to the first black frame insertion control signal terminal E1 is turned on, and the first black frame insertion control transistor T41 transmits the second voltage signal transmitted by the second voltage signal terminal VDD to the sixth node N6.

The fifth transistor T5 is turned on under the control of the first control signal from the first control signal terminal K1, and the fifth transistor T5 transmits the second voltage signal received by the sixth node N6 to the signal output terminal Out, so that the signal output terminal Out outputs a scanning signal.

Of course, in some other embodiments, referring to FIGS. 15 and 24, in a case where the shift register 310 includes a black frame insertion control sub-circuit 42, a display period further includes a black frame insertion phase M50 after the output phase M20. It will be understood that the black frame insertion phase M50 is also located after the initialization phase M40.

In the black frame insertion phase M50, the first decode sub-circuit 35 transmits the second voltage signal to the fifth node N5 under the control of at least one selection control signal terminal DX, and the black frame insertion control sub-circuit 42 transmits the second voltage signal received by the fifth node N5 to the signal output terminal Out under the control of the first control signal from the first control signal terminal K1, so that the signal output terminal Out outputs a scanning signal. It will be understood that the driving method of the shift register shown in FIG. 15 is similar to that of the shift register shown in FIG. 19, and will not be repeated here.

In some embodiments, a display period may further include a sensing phase after the black frame insertion phase M50. In the sensing phase, a shift register may be selected by the first decode sub-circuit to output a scanning signal, and may output the scanning signal to a pixel row connected to the selected shift register. It will be understood that, in the sensing phase, the driving method of the shift register is similar to the driving method in the selection phase and the output phase in a case where the shift register is selected to output a scanning signal, and will not be repeated here.

The above are only specific embodiments of the present disclosure, but the protection scope of the present disclosure is not limited thereto, and variations or substitutions that any person skilled in the art may conceive of within the technical scope disclosed by the present disclosure, should fall within the protection scope of the present disclosure. Therefore, the protection scope of the present disclosure should be subjected to the protection scope of the claims.

1. A shift register, comprising:
a first control sub-circuit, electrically connected to a first clock signal terminal and a first node, and configured to transmit the first clock signal to the first node under control of a first clock signal from the first clock signal terminal;
a first output sub-circuit, electrically connected to the first node, a first voltage signal terminal and a signal output terminal, and configured to transmit a first voltage signal from the first voltage signal terminal to the signal output terminal under control of a voltage of the first node;
a second control sub-circuit, electrically connected to the first node, a second clock signal terminal and a second node, and configured to transmit a second clock signal to the second node under control of the second clock signal from the second clock signal terminal and the voltage of the first node;
a second output sub-circuit, electrically connected to the second node, a third clock signal terminal and the signal output terminal, and configured to transmit a third clock signal from the third clock signal terminal to the signal output terminal under control of a voltage of the second node;
a first decode sub-circuit, electrically connected to a plurality of selection control signal terminals, the second clock signal terminal and a third node, and configured to: select the shift register to output no scanning signal under control of an operating voltage from at least one selection control signal terminal and the second clock signal, or select the shift register to output a scanning signal under control of a non-operating voltage of each selection control signal terminal of the plurality of selection control signal terminals and the second clock signal; and
a third control sub-circuit, electrically connected to the first voltage signal terminal, the second node, the third node and the signal output terminal, and configured to: transmit the first voltage signal to the second node and the signal output terminal in a case where the shift register is selected to output no scanning signal, and transmit the first voltage signal to the third node in a case where the shift register is selected to output a scanning signal.

2. The shift register according to claim 1, wherein the first decode sub-circuit includes:
a first transistor, wherein a control electrode and a first electrode of the first transistor are both electrically connected to the second clock signal terminal, and a second electrode of the first transistor is electrically connected to a fourth node; and
a plurality of second transistors, wherein a control electrode of each second transistor of the plurality of second transistors is electrically connected to a selection control signal terminal of the plurality of selection control signal terminals, first electrodes of the plurality of second transistors are all electrically connected to the fourth node, and second electrodes of the plurality of second transistors are all electrically connected to the third node.

3. The shift register according to claim 1, wherein the first decode sub-circuit is further electrically connected to a second voltage signal terminal, and the first decode sub-circuit includes:
a first transistor, wherein a control electrode of the first transistor is electrically connected to the second clock signal terminal, a first electrode of the first transistor is electrically connected to a fifth node, and a second electrode of the first transistor is electrically connected to the third node; and
a plurality of second transistors, wherein a control electrode of each second transistor of the plurality of second transistors is electrically connected to a selection control signal terminal of the plurality of selection control signal terminals, first electrodes of the plurality of second transistors are all electrically connected to the second voltage signal terminal, and second electrodes of the plurality of second transistors are all electrically connected to the fifth node.

4. The shift register according to claim 3, further comprising:
a black frame insertion control sub-circuit, electrically connected to a first control signal terminal, the fifth node and the signal output terminal, and configured to transmit a voltage of the fifth node to the signal output terminal under control of a first control signal from the first control signal terminal; or
the shift register further comprising a black frame insertion control sub-circuit, wherein the black frame insertion control sub-circuit is electrically connected to the first control signal terminal, the fifth node and the signal output terminal, and is configured to transmit the voltage of the fifth node to the signal output terminal, and is configured to transmit the from the first control signal terminal; the black frame insertion control sub-circuit includes a third transistor, a control electrode of the third transistor is electrically connected to the first control signal terminal, a first electrode of the third transistor is electrically connected to the fifth node, and a second electrode of the third transistor is electrically connected to the signal output terminal.

5. (canceled)

6. The shift register according to claim 1, further comprising:
a second decode sub-circuit, electrically connected to a plurality of black frame insertion control signal terminals, a first control signal terminal, a second voltage signal terminal and the signal output terminal, and configured to transmit a second voltage signal from the second voltage signal terminal to the signal output terminal under control of a black frame insertion control signal from at least one black frame insertion control signal terminal of the plurality of black frame insertion control signal terminals and a first control signal from the first control signal terminal.

7. The shift register according to claim 6, wherein the second decode sub-circuit includes:
a plurality of fourth transistors, wherein a control electrode of each fourth transistor of the plurality of fourth transistors is electrically connected to a black frame insertion control signal terminal of the plurality of black frame insertion control signal terminals, first electrodes of the plurality of fourth transistors ae all electrically connected to the second voltage signal terminal, and second electrode of the plurality of fourth transistors are all electrically connected to a sixth node; and
a fifth transistor, wherein a control electrode of the fifth transistor is electrically connected to the first control signal terminal, a first electrode of the fifth transistor is electrically connected to the sixth node, and a second electrode of the fifth transistor is electrically connected to the signal output terminal.

8. (canceled)

9. The shift register according to claim 1, wherein the third control sub-circuit includes:
a sixth transistor, wherein a control electrode of the sixth transistor is electrically connected to the third node, a first electrode of the sixth transistor is electrically connected to the first voltage signal terminal, and a second electrode of the sixth transistor is electrically connected to the second node;
a seventh transistor, wherein a control electrode of the seventh transistor is electrically connected to the third node, a first electrode of the seventh transistor is electrically connected to the first voltage signal terminal, and a second electrode of the seventh transistor is electrically connected to the signal output terminal; and
an eighth transistor, wherein a control electrode of the eighth transistor is electrically connected to the second node, a first electrode of the eighth transistor is electrically connected to the first voltage signal terminal, and a second electrode of the eighth transistor is electrically connected to the third node.

10. The shift register according to claim 9, wherein the sixth transistor is a dual-gate transistor including two sub-transistors connected in series, and the two sub-transistors are connected through a seventh node; and the shift register further comprises: an anti-leakage sub-circuit, electrically connected to the second node, a second voltage signal terminal and the seventh node, and configured to transmit a second voltage signal to the seventh node under control of the voltage of the second node; or
the sixth transistor is a dual-gate transistor including two sub-transistors connected in series, and the two sub-transistors are connected through a seventh node; the shift register further comprises an anti-leakage sub-circuit; the anti-leakage sub-circuit is electrically connected to the second node, a second voltage signal terminal and the seventh node, and is configured to transmit a second voltage signal to the seventh node under control of the voltage of the second node; the anti-leakage sub-circuit includes a ninth transistor; a control electrode of the ninth transitory electrically connected to the second node, a first electrode of the ninth transistor is electrically connected to the second voltage signal terminal, and a second electrode of the ninth transistor is electrically connected to the seventh node.

11. (canceled)

12. The shift transistor according to claim 1, wherein the third control sub-circuit is further electrically connected to the first node, and the third control sub-circuit is further configured to, in a case where the shift register is selected to output no scanning signal, transmit the first voltage signal to the first node; or
the third control sub-circuit is further electrically connected to the first node, and the third control sub-circuit is further configured to, in a case where the shift register is selected to output no scanning signal, transmit the first voltage signal to the first node; the third control sub-circuit further includes a tenth transistor, wherein a control electrode of the tenth transistor is electrically connected to the third node, a first electrode of the tenth transistor is electrically connected to the first voltage signal terminal, and a second electrode of the tenth transistor is electorally connected to the first node.

13. (canceled)

14. The shift register according to claim 9, further comprising:
a time-division selection sub-circuit electrically connected to a second control signal terminal, a third control signal terminal, the first decode sub-circuit, the third node and an eighth node; wherein the time-division selection sub-circuit is configured to: electrically connect the first decode sub-circuit to the third node under control of a second control signal from the second control signal terminal, and electrically connect the first decode sub-circuit to the eighth node under control of a third control signal from the third control signal terminal; the first decode sub-circuit is electrically connected to the third node through the time-division selection sub-circuit; and
a fourth control sub-circuit, electrically connected to the first voltage signal terminal the second node, the eighth node and the signal output terminal, and configured to: transmit the first voltage signal to the second node and the signal output terminal in a case where the shift register is selected to output no scanning signal, and transmit the first voltage signal to the eighth node in a case where the shift register is selected to output a scanning signal.

15. The shift register according to claim 14, wherein the time-division selection sub-circuit includes:
an eleventh transistor, wherein a control electrode of the eleventh transistor is electrically connected to the second control signal terminal, a first electrode of the eleventh transistor is electrically connected to the first decode sub-circuit, and a second electrode of the eleventh transistor is electrically connected to the third node; and
a twelfth transistor, wherein a control electrode of the twelfth transistor is electrically connected to the third control signal terminal, a first electrode of the twelfth transistor is electrically connected to the first decode sub-circuit, and a second electrode of the twelfth transistor is electrically connected to the eighth node;
wherein in a display period, one of the second control signal terminal and the third control signal terminal transmits a corresponding control signal, and the second control signal terminal and the third control signal terminal alternately transmit a corresponding control signal; and/or
the fourth control sub-circuit includes:
a thirteenth transitory, wherein a control electrode of the thirteenth transitory is electrically connected to the eight node, a first electrode of the thirteenth transistor is electrically connected to the first voltage signal terminal, and a second electrode of the thirteenth transistor is electrically connected to the second node;
a fourteenth transistor, wherein a control electrode of the fourteenth transistor is electronically connected to the eighth node, a first electrode of the fourteenth transistor is electrically connected to the first voltage signal terminal, and a second electrode of the fourteenth transistor is electrically connected to the signal output terminal;
a fifteenth transistor, wherein a control electrode of the fifteenth transistor is electrically connected to the second node, a first electrode of the fifteenth transitory is electrically connected to the first voltage signal terminal, and a second electrode of the fifteenth transistor is electrically connected to the eighth node; and
a sixteenth transistor, wherein a control electrode of the sixteenth transistor is electrically connected to the eighth node, a first electrode of the sixteenth transistor is electrically connected to the first voltage signal terminal, and a second electrode of the sixteenth transistor is electrically connected to the first node.

16. (canceled)

17. The shift register according to claim 1, wherein
the first control sub-circuit includes a seventeenth transistor, a control electrode and a first electrode of the seventeenth transistor are both electrically connected to the first clock signal terminal, and a second electrode of the seventeenth transistor is electrically connected to the first node;
the first output sub-circuit includes an eighteenth transistor, a control electrode of the eighteenth transistor is electrically connected to the first node, a first electrode of the eighteenth transistor is electrically connected to the first voltage signal terminal, and a second electrode of the eighteenth transistor is electrically connected to the signal output terminal;
the second control sub-circuit includes a nineteenth transistor and a twentieth transistor, a control electrode and a first electrode of the nineteenth transistor are both electrically connected to the second clock signal terminal, and a second electrode of the nineteenth transistor is electrically connected to a first electrode of the twentieth transistor; a control electrode of the twentieth transistor is electrically connected to the first node, and a second electrode of the twentieth transistor is electrically connected to the second node; and
the second output sub-circuit includes a twenty-first transistor, a control electrode of the twenty-first transistor is electrically connected to the second node, a first electrode of the twenty-first transistor is electrically connected to the third clock signal terminal, and a second electrode of the twenty-first transistor is electrically connected to the signal output terminal.

18. The shift register according to claim 1, further comprising:
a reset sub-circuit, electrically connected to the third clock signal terminal, the first voltage signal terminal and the first node, and configured to transmit the first voltage signal to the first node under control of the third clock signal;
an initialization sub-circuit, electrically connected to the first clock signal terminal, the first voltage signal terminal and the third node, and configured to transmit the first voltage signal to the third node under control of the first clock signal;
a first energy-storing sub-circuit, electrically connected to the first voltage signal terminal and the first node and configured to maintain the voltage of the first node;
a second energy-storing sub-circuit, electrically connected to the second node and the signal output terminal and configured to maintain the voltage of the second node; and
a third energy-storing sub-circuit, electrically connected to the third node and the first voltage signal terminal and configured to maintain a voltage of the third node.

19. The shift register according to claim 18, wherein
the reset sub-circuit includes a twenty-second transistor, a control electrode of the twenty-second transistor is electrically connected to the third clock signal terminal, a first electrode of the twenty-second transistor is electrically connected to the first voltage signal terminal, and a second electrode of the twenty-second transistor is electrically connected to the first node;
the initialization sub-circuit includes a twenty-third transistor, a control electrode of the twenty-third transistor is electrically connected to the first clock signal terminal, a first electrode of the twenty-third transistor is electrically connected to the first voltage signal terminal, and a second electrode of the twenty-third transistor is electrically connected to the third node;
the first energy-storing sub-circuit includes a first capacitor, a plate of the first capacitor is electrically connected to the first voltage signal terminal, and another plate of the first capacitor is electrically connected to the first node;
the second energy-storing sub-circuit includes a second capacitor, a plate of the second capacitor is electrically connected to the second node, and another plate of the second capacitor is electrically connected to the signal output terminal;
the third energy-storing sub-circuit includes a third capacitor, a plate of the third capacitor is electrically connected to the first voltage signal terminal, and another plate of the third capacitor is electrically connected to the third node.

20-23. (canceled)

24. A gate driving circuit, comprising:
a plurality of the shift registers each according to claim 1; and
a plurality of groups of selection control signal lines, wherein each group of selection control signal lines includes two selection control signal lines, and each selection control signal line forms a selection control signal terminal; a first decode sub-circuit of a shift register is electrically connected to a selection control signal line in each group of selection control signal lines, and the selection control signal line forms a selection control signal terminal.

25. The gate driving circuit according to claim 24, wherein
every four shift registers constitute a shift register group, and the four shift registers included in the shift register group are sequentially arranged as a first-stage shift register, a second-stage shift register, a third-stage shift register and a fourth-stage shift register; and
the gate driving circuit further comprises:
a first clock signal line electrically connected to a first clock signal terminal of the first-stage shift register, a third clock signal terminal of the second-stage shift register, and a second clock signal terminal of the third-stage shift register;
a second clock signal line electrically connected to a first clock signal terminal of the second-stage shift register, a third clock signal terminal of the third-stage shift register, and a second clock signal terminal of the fourth-stage shift register;
a third clock signal line electrically connected to a second clock signal terminal of the first-stage shift register, a first clock signal terminal of the third-stage shift register, and a third clock signal terminal of the fourth-stage shift register; and
a fourth clock signal line electrically connected to a third clock signal terminal of the first-stage shift register, a second clock signal terminal of the second-stage shift register, and a first clock signal terminal of the fourth-stage shift register.

26. The gate driving circuit according to claim 25, wherein
one of the two selection control signal lines of each group of selection control signal lines transmits an operating voltage, and another of the two selection control signal lines of each group of selection control signal lines transmits a non-operating voltage; and
the first clock signal line, the second clock signal line, the third clock signal line and the fourth clock signal line sequentially transmit the operating voltage.

27. The gate driving circuit according to claim 24, wherein
the shift register further includes a second decode sub-circuit, the second decode sub-circuit is electrically connected to a selection control signal line of each group of selection control signal lines, and the selection control signal line forms a black frame insertion control signal terminal; and
the second decode sub-circuit and the first decode sub-circuit are electrically connected to a same selection control signal line or different selection control signal lines in a same group of selection control signal lines.

28. A display device, comprising:
the shift register according to claim 1.

29. A display device, comprising:
the gate driving circuit according to claim 24.
